(19) United States
(12) Patent Application Publication
(10) Pub. No.: US 2015/0349015 A1
(43) Pub. Date: Dec. 3, 2015

(54) SEMICONDUCTOR DEVICE AND MANUFACTURING METHOD THEREOF

(71) Applicant: Renesas Electronics Corporation, Kawasaki-shi (JP)

(72) Inventor: Tadashi Yamaguchi, Kanagawa (JP)

(21) Appl. No.: 14/712,898

(22) Filed: May 14, 2015

(30) Foreign Application Priority Data
May 27, 2014 (JP) 2014-109583

(51) Int. Cl. H01L 27/146

(52) U.S. Cl. CPC H01L 27/14645; H01L 27/14621; H01L 27/14627; H01L 27/14625; H01L 27/14636; H01L 27/14685; H01L 27/14689

(57) ABSTRACT

A semiconductor device having an improved performance is disclosed. In the semiconductor device, an insulating film part is formed over a main surface of a semiconductor substrate so as to cover a photodiode, a concave portion is formed in the upper surface of the insulating film part in a portion that overlaps the center of the photodiode, and a transmission film is formed over the insulating film part so as to close the concave portion. A space is formed by the concave portion and the transmission film, and the space is arranged to overlap the center of the photodiode in plan view.

### CROSS-REFERENCE TO RELATED APPLICATIONS

The disclosure of Japanese Patent Application No. 2014-109583 filed on May 27, 2014 including the specification, drawings and abstract is incorporated herein by reference in its entirety.

### BACKGROUND

The present invention relates to a semiconductor device and a manufacturing method thereof, and can be preferably used, for example, in a semiconductor device including a solid-state image sensor and a manufacturing method thereof.

CMOS (Complementary Metal Oxide Semiconductor) image sensors using a CMOS are being developed as solid-state image sensors (hereinafter, also simply referred to as image sensors) to be used in digital cameras, and the like. This CMOS image sensor has a plurality of pixels that are arranged in a matrix pattern for respectively detecting light. A photoelectric conversion element, such as a photodiode for detecting light to generate a charge, is formed in each of the pixels.

In such a CMOS image sensor, an optical waveguide is formed above the photodiode in each of the pixels, in order to improve an efficiency at which light enters each of the pixels with an increase in the number of the pixels.

Japanese Unexamined Patent Application Publication No. 2012-186364 (Patent Document 1) discloses a technique in which a light receiving part to be formed in a semiconductor substrate to convert light into a signal charge and an optical waveguide having a core formed in a light transmission layer are provided in a solid-state image sensor. Additionally, Non-Patent Document 1 discloses a technique in which an optical waveguide including a silicon nitride film is formed above a photodiode.

### RELATED ART DOCUMENT

### Patent Document

[Patent Document 1] Japanese Unexamined Patent Application Publication No. 2012-186364

### Non-Patent Document

[Non-Patent Document 1] H. Watanabe et al., “A 1.4 microm front-side illuminated image sensor with novel light guiding structure consisting of stacked lightpipes”, 2011 IEEE International Electron Devices Meeting (IEDM 2011), pp. 179-182 (2011).

### SUMMARY

In semiconductor devices including such a CMOS image sensor, the refractive index inside an optical waveguide can be larger than that outside the optical waveguide: by forming, of insulating films including, for example, a silicon oxide film, a concave portion in a section that is to serve as the optical waveguide; and by embedding an insulating film, which includes, for example, a silicon nitride film and is to serve as the optical waveguide, in the formed concave portion.

However, it is difficult to fill the inside of the concave portion with an insulating film including, for example, a silicon nitride film. It is also difficult to flatten an insulating film formed outside the concave portion by grinding or polishing after the concave portion is filled with the insulating film.

Further, incident light to enter a photodiode is attenuated while passing through an optical waveguide including an insulating film embedded in the concave portion, and hence the light amount of the incident light to enter the photodiode is decreased, which leads to a decrease in the sensitivity of the CMOS image sensor and a decrease in the performance of the semiconductor device.

Other problems and new characteristics will become clear from the description and accompanying drawings of the present specification.

According to one embodiment, in a semiconductor device, an insulating film part is formed over a main surface of a semiconductor substrate so as to cover a photodiode; a concave portion is formed in the upper surface of the insulating film part in a portion that overlaps the center of the photodiode; and a transmission film is formed over the insulating film part so as to close the concave portion. A space is formed by the concave portion and the transmission film, and the space is arranged to overlap the center of the photodiode in plan view.

According to another embodiment, in a manufacturing method of a semiconductor device, an insulating film part is formed over a main surface of a semiconductor substrate so as to cover a photodiode; a concave portion is formed in the upper surface of the insulating film part in a portion that overlaps the center of the photodiode; and a transmission film is formed over the insulating film part so as to close the concave portion. A space is formed by the concave portion and the transmission film, and the space is arranged to overlap the center of the photodiode in plan view.

According to one embodiment, the performance of a semiconductor device can be improved.

### BRIEF DESCRIPTION OF THE DRAWINGS

FIG. 1 is a circuit diagram illustrating a configuration example of a pixel;

FIG. 2 is a plan view illustrating a pixel in a semiconductor device of First Embodiment;

FIG. 3 is a plan view illustrating a semiconductor substrate and element regions where the semiconductor device of First Embodiment is to be formed;

FIG. 4 a plan view illustrating a transistor formed in a peripheral circuit region of the semiconductor device of First Embodiment;

FIG. 5 is a sectional view illustrating a configuration of the semiconductor device of First Embodiment;

FIG. 6 is a sectional view illustrating a configuration of the semiconductor device of First Embodiment;

FIG. 7 is a plan view illustrating an example of a pixel of the semiconductor device of First Embodiment;

FIG. 8 is a plan view illustrating another example of the pixel of the semiconductor device of First Embodiment;

FIG. 9 is a sectional view illustrating another example of the pixel of the semiconductor device of First Embodiment;

FIG. 10 is a graph schematically showing changes in impurity concentration at the boundary between an n−type well and a p−type well;

FIG. 11 is a manufacturing process flow chart illustrating part of manufacturing steps of the semiconductor device of First Embodiment;

FIG. 12 is a manufacturing process flow chart illustrating part of the manufacturing steps of the semiconductor device of First Embodiment;

FIG. 13 is a sectional view illustrating a manufacturing step of the semiconductor device of First Embodiment;

FIG. 14 is a sectional view illustrating a manufacturing step of the semiconductor device of First Embodiment;

FIG. 15 is a sectional view illustrating a manufacturing step of the semiconductor device of First Embodiment;

FIG. 16 is a sectional view illustrating a manufacturing step of the semiconductor device of First Embodiment;

FIG. 17 is a sectional view illustrating a manufacturing step of the semiconductor device of First Embodiment;

FIG. 18 is a sectional view illustrating a manufacturing step of the semiconductor device of First Embodiment;

FIG. 19 is a sectional view illustrating a manufacturing step of the semiconductor device of First Embodiment;

FIG. 20 is a sectional view illustrating a manufacturing step of the semiconductor device of First Embodiment;

FIG. 21 is a sectional view illustrating a manufacturing step of the semiconductor device of First Embodiment;

FIG. 22 is a sectional view illustrating a manufacturing step of the semiconductor device of First Embodiment;

FIG. 23 is a sectional view illustrating a manufacturing step of the semiconductor device of First Embodiment;

FIG. 24 is a sectional view illustrating a manufacturing step of the semiconductor device of First Embodiment;

FIG. 25 is a sectional view illustrating a manufacturing step of the semiconductor device of First Embodiment;

FIG. 26 is a sectional view illustrating a manufacturing step of the semiconductor device of First Embodiment;

FIG. 27 is a sectional view illustrating a manufacturing step of the semiconductor device of First Embodiment;

FIG. 28 is a sectional view illustrating a manufacturing step of the semiconductor device of First Embodiment;

FIG. 29 is a sectional view illustrating a configuration of a semiconductor device of a variation of First Embodiment;

FIG. 30 is a sectional view illustrating a configuration of the semiconductor device of the variation of First Embodiment;

FIG. 31 is a sectional view illustrating a manufacturing step of the semiconductor device of the variation of First Embodiment;

FIG. 32 is a sectional view illustrating a manufacturing step of the semiconductor device of the variation of First Embodiment;

FIG. 33 is a sectional view illustrating a manufacturing step of the semiconductor device of the variation of First Embodiment;

FIG. 34 is a sectional view illustrating a manufacturing step of the semiconductor device of the variation of First Embodiment;

FIG. 35 is a sectional view illustrating a manufacturing step of the semiconductor device of the variation of First Embodiment;

FIG. 36 is a sectional view illustrating a manufacturing step of the semiconductor device of the variation of First Embodiment;

FIG. 37 is a sectional view illustrating a manufacturing step of the semiconductor device of the variation of First Embodiment;

FIG. 38 is a sectional view illustrating a manufacturing step of the semiconductor device of the variation of First Embodiment;

FIG. 39 is a sectional view illustrating a configuration of a semiconductor device of First Comparative Example;

FIG. 40 is a sectional view illustrating a configuration of a semiconductor device of Second Comparative Example;

FIG. 41 is a sectional view illustrating a configuration of a semiconductor device of Second Embodiment;

FIG. 42 is a manufacturing process flow chart illustrating part of manufacturing steps of the semiconductor device of Second Embodiment;

FIG. 43 is a sectional view illustrating a manufacturing step of the semiconductor device of Second Embodiment;

FIG. 44 is a sectional view illustrating a manufacturing step of the semiconductor device of Second Embodiment;

FIG. 45 is a sectional view illustrating a manufacturing step of the semiconductor device of Second Embodiment;

FIG. 46 is a sectional view illustrating a configuration of a semiconductor device of Third Embodiment;

FIG. 47 is a sectional view illustrating a configuration of the semiconductor device of Third Embodiment;

FIG. 48 is a manufacturing process flow chart illustrating part of manufacturing steps of the semiconductor device of Third Embodiment;

FIG. 49 is a sectional view illustrating a manufacturing step of the semiconductor device of Third Embodiment;

FIG. 50 is a sectional view illustrating a manufacturing step of the semiconductor device of Third Embodiment; and

FIG. 51 is a sectional view illustrating a manufacturing step of the semiconductor device of Third Embodiment.

### DETAILED DESCRIPTION

When necessary for convenience in the following embodiment, description is given by dividing the embodiment into a plurality of sections or embodiments; however, unless otherwise indicated, they are not independent of one another, but one is related with the other part or the whole as a modification example, a detail, supplementary description, etc.

When referring to the number of elements, etc. (including number of pieces, numerical value, quantity, range, etc.) in the following embodiment, unless otherwise indicated or except when the number is obviously limited to specific numbers in principle, the number is not limited to the specific ones but may be more or less than the specific numbers.

In the following embodiments, it is needless to say that a constituent element (including an element step, etc.) is not always essential, unless otherwise indicated or except when considered to be clearly essential in principle. Similarly, in the following embodiments, when shapes and positional relations, etc., of constituent elements, etc., are referred to, those substantially the same or similar to the shapes, etc., should also be included, unless otherwise indicated or except when considered to be clearly otherwise in principle. This also applies to the aforementioned numerical values and ranges.

Hereinafter, typical embodiments will be described in detail with reference to the accompanying drawings. In each view for explaining the embodiments, components having the same function will be denoted with the same reference numerals, and duplicative description thereof will be omitted. In the following embodiments, description of the same or similar parts will not be repeated in principle, unless particularly necessary.

In the views to be used in the embodiments, hatching may be omitted even in a sectional view for easy understanding of the view. Conversely, hatching may be used even in a plan view for the same reason.

In a sectional view or a plan view, the size of each part does not correspond to that of an actual device, and a specific part maybe displayed to be relatively large for the same reason. Even if a plan view or a sectional view corresponds, the size of each part may be displayed after being changed.

When a range is represented by A to B in the following embodiments, it represents from A to B (inclusive), unless otherwise indicated.

### First Embodiment

Hereinafter, a structure and a manufacturing steps of a semiconductor device of First Embodiment will be described in detail with reference to the accompanying drawings. In First Embodiment, an example will be described, in which the semiconductor device includes a CMOS image sensor.

<Configuration of Semiconductor Device>

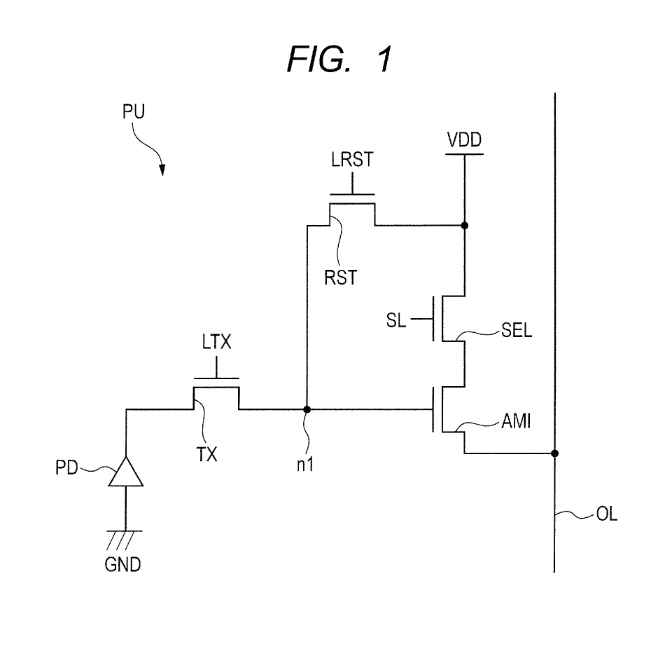

FIG. 1 is a circuit diagram illustrating a configuration example of a pixel. One pixel is illustrated in FIG. 1, but the number of the pixels actually used in an electronic device, such as a camera, may be several millions.

As illustrated in FIG. 1, a pixel PU is formed, for example, by a photodiode PD and four MOSFETs. These MOSFETs are of an n-channel type; and RST is a reset transistor, TX is a transfer transistor, SEL is a selection transistor, and AMI is an amplification transistor. The transfer transistor TX transfers a charge generated by the photodiode PD. Other transistors or elements such as a capacitive element may be incorporated in addition to these transistors. Various variations and application forms are present in the coupling of theses transistors. Herein, the MOSFET is an abbreviation for Metal Oxide Semiconductor Field Effect Transistor, and may also be indicated by MISFET. Additionally, the FET is an abbreviation for Field Effect Transistor.

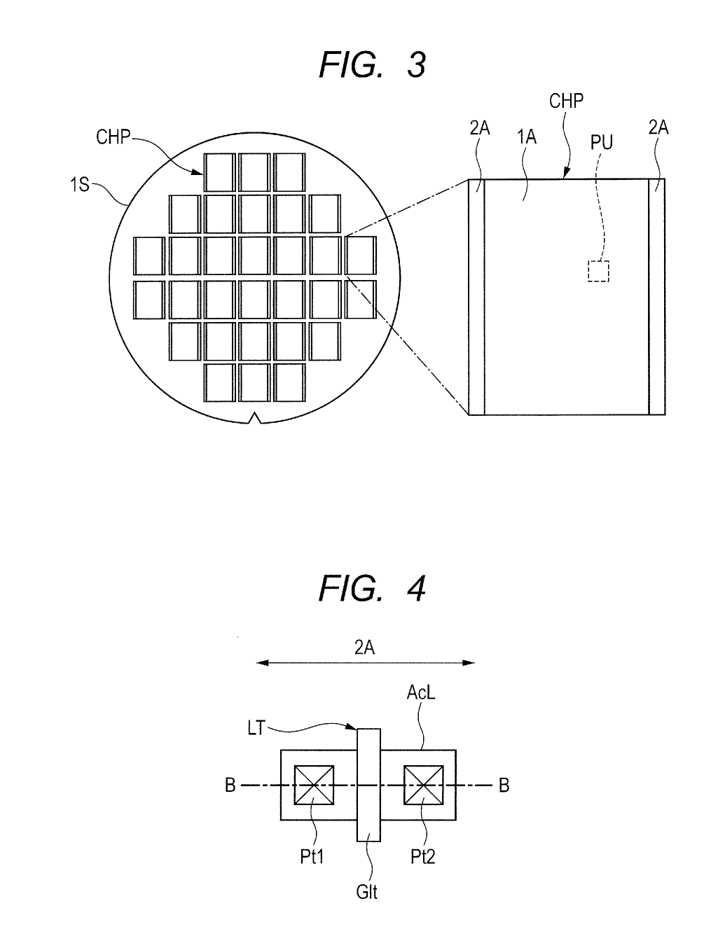

A plurality of the pixels PU are arranged in a pixel region 1A that will be described later with reference to FIG. 3.

In the circuit example illustrated in FIG. 1, the photodiode PD and the transfer transistor TX are coupled in series between a ground potential GND and a node n1. The reset transistor RST is coupled between the node n1 and a power supply potential VDD. The selection transistor SEL and the amplification transistor AMI are coupled in series between the power supply potential VDD and an output line OL. The gate electrode of this amplification transistor AMI is coupled to the node n1. The gate electrode of the reset transistor RST is coupled to a reset line LRST. The gate electrode of the selection transistor SEL is coupled to a selection line SL, while that of the transfer transistor TX is coupled to a transfer line LTX.

For example, the transfer line LTX and the reset line LRST are activated to have an H-level, thereby causing the transfer transistor TX and the reset transistor RST to be in an ON state. As a result, the photodiode PD is depleted by transferring the charges stored in the photodiode PD. Thereafter, the transfer transistor TX is caused to be in an OFF state.

Thereafter, when a mechanical shutter in an electronic device such as, for example, a camera is opened, charges are generated in the photodiode PD by incident light while the shutter is being opened, the charges being stored therein. That is, the photodiode PD generates a charge by receiving incident light. In other words, the photodiode PD receives incident light to convert into a charge.

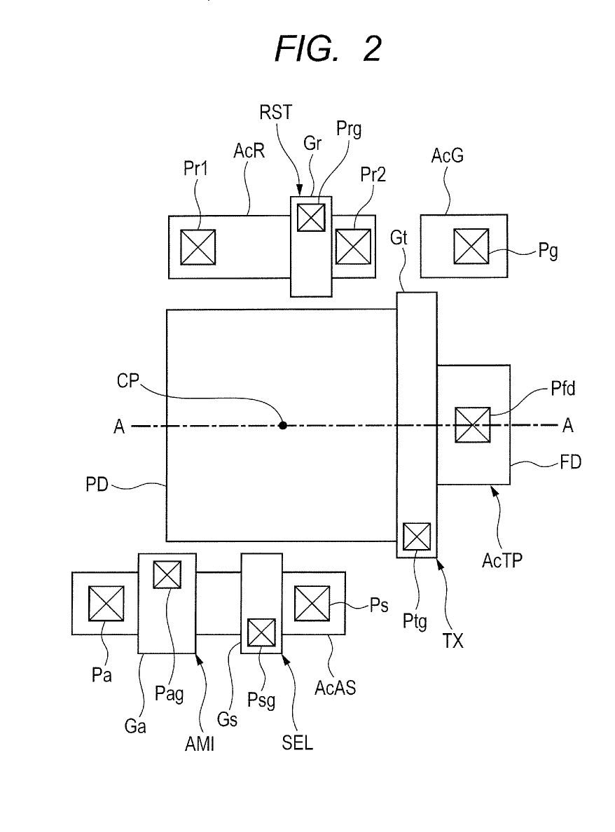

Subsequently, the reset line LRST is activated to have an L-level after the shutter is closed, thereby causing the reset transistor RST to be in an OFF state. Further, the selection line SL and the transfer line LTX are activated to have an H-level, thereby causing the selection transistor SEL and the transfer transistor TX to be in an ON state. Thereby, the charge generated by the photodiode PD is transferred to an end portion of the transfer transistor TX (floating diffusion FD illustrated in FIG. 2 described later), the end portion being near to the node n1. At the time, the electric potential of the floating diffusion FD is changed to a value corresponding to the charge transferred from the photodiode PD, and the value is amplified by the amplification transistor AMI to appear in the output line OL. The electric potential of the output line OL is read out as an output signal.

FIG. 2 is a plan view illustrating a pixel in the semiconductor device of First Embodiment.

As illustrated in FIG. 2, the pixel PU (see FIG. 1) in the semiconductor device of First Embodiment has both an active region AcTP, in which the photodiode PD and the transfer transistor TX are arranged, and an active region AcR, in which the reset transistor RST is arranged. The pixel PU further has both an active region AcAS, in which the selection transistor SEL and the amplification transistor AMI are arranged, and an active region AcG, in which a plug Pg coupled to a ground potential line is arranged.

A gate electrode Gr is arranged in the active region AcR, and plugs Pr1 and Pr2 are arranged over a source/drain region on both sides of the gate electrode Gr. The reset transistor RST is formed by the gate electrode Gr and the source/drain region.

A gate electrode Gt is arranged in the active region AcTP, and the photodiode PD is arranged, in plan view, on one of both sides of the gate electrode Gt. The floating diffusion FD, having a function as a charge storage part or a floating diffusion layer, is arranged, in plan view, on the other of both sides of the gate electrode Gt. The photodiode PD is a p-n junction diode, and is formed, for example, by a plurality of n−type or p−type impurity regions, i.e., semiconductor regions. The floating diffusion FD is formed, for example, by an n−type impurity region, i.e., by a semiconductor region. A plug Pfd is arranged over the floating diffusion FD.

Gate electrodes Ga and Gs are arranged in the active region AcAS; a plug Pa is arranged in an end portion of the active region AcAS near to the gate electrode Ga; and a plug Ps is arranged in an end portion thereof near to the gate electrode Gs. Both sides of each of the gate electrodes Ga and Gs are source/drain regions, and the selection transistor SEL and the amplification transistor AMI, which are coupled in series, are formed by the gate electrodes Ga and Gs and the source/drain regions.

The plug Pg is arranged over the active region AcG. The plug Pg is coupled to the ground potential line. Accordingly, the active region AcG serves as a power supply region for applying a ground potential GND to a well region of a semiconductor substrate.

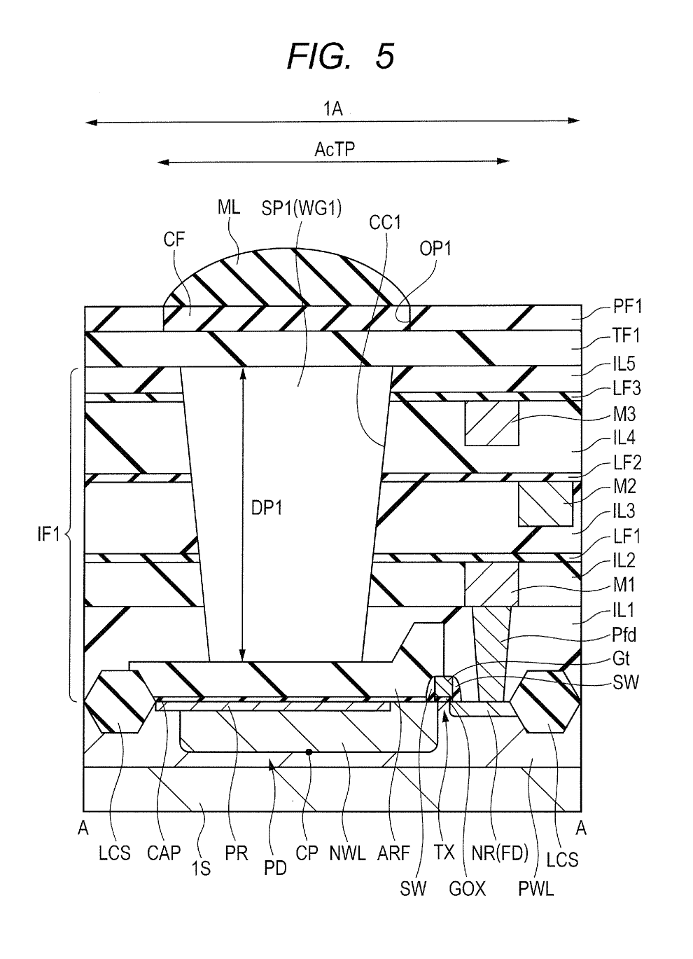

The above plugs Pr1, Pr2, Pg, Pfd, Pa, and Ps are coupled together by a plurality of wiring layers (e.g., wiring M1 to M3 illustrated in FIG. 5 described later). Plugs Prg, Ptg, Pag, and Psg, respectively located over the gate electrodes Gr, Gt, Ga, and Gs, are coupled together by a plurality of wiring layers (e.g., wiring M1 to M3 illustrated in FIG. 5 described later). Thereby, the circuit illustrated in FIG. 1 can be formed.

FIG. 3 is a plan view illustrating the semiconductor substrate and element regions where the semiconductor device of First Embodiment is to be formed. As illustrated in FIG. 3, a semiconductor substrate 1S has a plurality of element regions CHP on the top surface side of the semiconductor substrate 1S, and one element region CHP has a pixel region 1A and a peripheral circuit regions 2A different from the pixel region 1A. A plurality of pixels PU are arranged in the pixel region 1A. Accordingly, the aforementioned active region AcTP is formed in the pixel region 1A on the top surface side of the semiconductor substrate 1S. A logic circuit is arranged in the peripheral circuit region 2A. The logic circuit calculates, for example, an output signal outputted from the pixel region 1A, so that image data is outputted based on a result of the calculation.

Herein, the semiconductor substrate 1S should have both the top surface as one main surface and the rear surface as the other main surface located opposite to the top surface, and the element region CHP should be formed on the top surface side.

FIG. 4 is a plan view illustrating a transistor formed in the peripheral circuit region of the semiconductor device of First Embodiment.

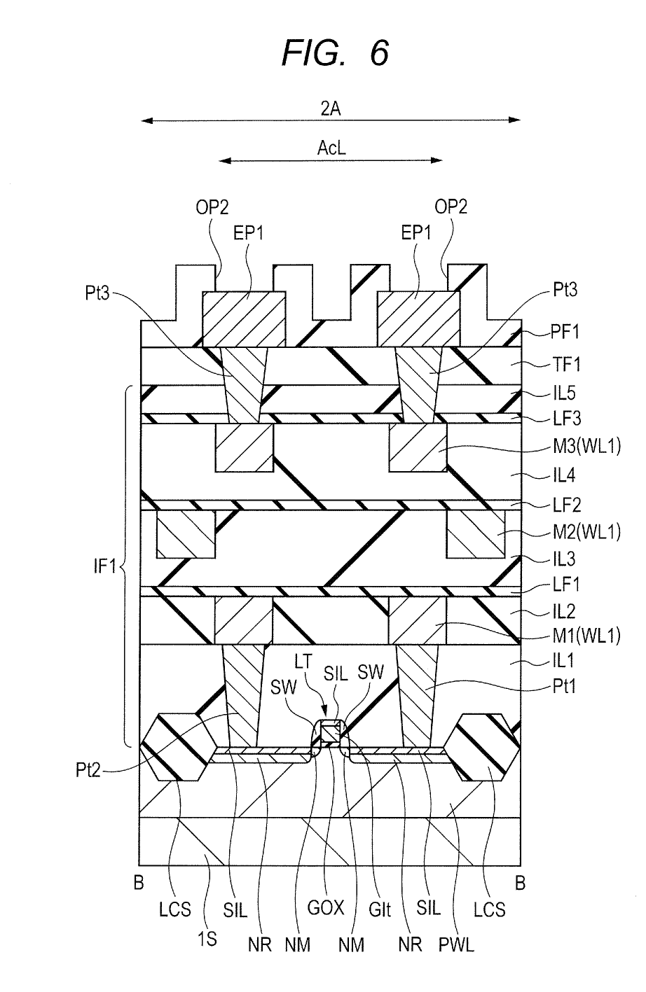

As illustrated in FIG. 4, a transistor LT, as a logic transistor, is arranged in the peripheral circuit region 2A. The transistor LT is formed by both an N−type MOSFET (NMOSFET), in which an electron serves as a carrier, and a P−type MOSFET, in which a hole serves as a carrier; and the transistor LT illustrated in FIG. 4 is one of the transistors that form a logic circuit, for example, NMOSFETs. An active region AcL is formed in the peripheral circuit region 2A on the top surface side of the semiconductor substrate 1S. A gate electrode Glt is arranged in the active region AcL, and a source/drain region, including a high concentration semiconductor region NR that will be described later with reference to FIG. 6, is formed on both sides of the gate electrode Glt and formed inside the active region AcL. Plugs Pt1 and Pt2 are arranged over the source/drain region, i.e., over the active region AcL.

Only one transistor LT is illustrated in FIG. 4. However, a plurality of transistors are arranged in the peripheral circuit region 2A. A logic circuit can be formed by coupling together the plugs located over the source/drain regions of these transistors or located over the gate electrodes with a plurality of wiring layers (e.g., wiring M1 to M3 illustrated in FIG. 6 described later). Alternatively, an element other than a transistor, such as, for example, a capacitive element, or a transistor having another configuration may be incorporated in the logic circuit.

Hereinafter, an example will be described, in which the transistor LT is an n-channel type MISFET, but the transistor LT may be a p-channel type MISFET to be used, for example, when a CMISFET is formed.

<Element Structure in Pixel Region and Peripheral Circuit Region>

Subsequently, element structures in the pixel region and the peripheral circuit region will be described. FIGS. 5 and 6 are sectional views each illustrating the configuration of the semiconductor device of First Embodiment. FIG. 5 corresponds to the A-A section in FIG. 2. FIG. 6 corresponds to the B-B section in FIG. 4.

As illustrated in FIG. 5, the photodiode PD, including a p−type well PWL and an n−type well NWL, and the transfer transistor TX are formed in the active region AcTP of the pixel region 1A that is a partial region of the top surface of the semiconductor substrate 1S, as a main surface thereof. As illustrated in FIG. 6, the transistor LT is formed in the active region AcL of the peripheral circuit region 2A that is another region of the top surface of the semiconductor substrate 1S, as a main surface thereof.

The semiconductor substrate 1S is formed from single crystalline silicon including n−type impurities (donors) such as, for example, phosphorus (P) and arsenic (As). An element isolation region LCS is arranged at the outer periphery of the active region AcTP. Thus, the exposed region of the semiconductor substrate 1S, surrounded by the element isolation region LCS, serves as an active region such as the active region AcTP.

The p−type well PWL, as a semiconductor region into which p−type impurities such as boron (B) have been introduced, is formed in the active region AcTP and the active region AcL.

As illustrated in FIG. 5, the n−type well NWL, as a semiconductor region into which n−type impurities such as phosphorus (P) and arsenic (As) have been introduced, is formed in the active region AcTP of the pixel region 1A so as to be included in the p−type well PWL. The photodiode PD is formed by the p−type well PWL and the n−type well NWL.

A p+ type semiconductor region PR is formed in part of the top surface of the n−type well NWL. The p+ type semiconductor region PR is formed in order to control the generation of electrons that occurs based on many interface states formed in the top surface of the semiconductor substrate 1S. That is, an increase in dark current may be caused in the top surface region of the semiconductor substrate 1S, because an electron is generated due to an influence of the interface state, even in a state where light is not radiated. Accordingly, the generation of an electron, which may occur in a state where light is not radiated, can be controlled by forming, in the top surface of the n−type well NWL in which an electron serves as a majority carrier, the p+ type semiconductor region PR in which a hole serves as a majority carrier, thereby allowing an increase in a dark current to be controlled.

The gate electrode Gt is formed to overlap part of the n−type well NWL in plan view. The gate electrode Gt is arranged over the semiconductor substrate 1S via a gate insulating film GOX, and a sidewall SW, as a sidewall insulating film, is formed in the sidewall on both sides of the gate electrode Gt.

In the specification of the present application, “in plan view” means the case where it is viewed from the direction perpendicular to the top surface of the semiconductor substrate 1S as a main surface thereof.

The n−type high concentration semiconductor region NR, into which n−type impurities such as, for example, phosphorus (P) and arsenic (As) have been introduced, is formed on one side of the gate electrode Gt (the side opposite to the photodiode PD). The n−type high concentration semiconductor region NR is a semiconductor region serving as the floating diffusion FD, and is also the drain region of the transfer transistor TX.

A cap insulating film CAP is formed in the top surface of the photodiode PD, i.e., in the top surfaces of both the n−type well NWL and the p+ type semiconductor region PR. The cap insulating film CAP is formed in order to maintain the top surface property of the semiconductor substrate 1S, i.e., the interfacial property thereof in good condition. An antireflection film ARF is formed over the cap insulating film CAP. That is, the antireflection film ARF is formed over the n−type well NWL.

On the other hand, the gate electrode Glt is formed, via the gate insulating film GOX, over the p−type well PWL in the active region AcL in the peripheral circuit region 2A, and the sidewall SW is formed in the sidewall on both sides of the gate electrode Glt, as illustrated in FIG. 6. A source/drain region is formed in the p−type well PWL located further on both sides of the gate electrode Glt, in the sidewall on both sides of which the sidewall SW is formed. The source/drain region has an LDD (Lightly Doped Drain) structure, and includes both an n−type low concentration semiconductor region NM, i.e., an n− type semiconductor region NM and the n−type high concentration semiconductor region NR, i.e., an n+ type semiconductor region NR. A silicide layer SIL, including a metal silicide such as, for example, a nickel silicide, is formed in the top surface of the n−type high concentration semiconductor region NR.

The silicide layer is not formed in the top surface of the n−type high concentration semiconductor region NR serving as the floating diffusion FD. That is, the silicide layer is not formed in an upper layer portion of the floating diffusion FD.

An interlayer insulating film IL1 is formed in the pixel region 1A so as to cover the semiconductor substrate 1S including the gate electrode Gt and the antireflection film ARF, and the plug Pfd is formed, the plug Pfd reaching the n−type high concentration semiconductor region NR as the floating diffusion FD by penetrating the interlayer insulating film IL1. That is, the interlayer insulating film IL1 is formed, via the antireflection film ARF and the cap insulating film CAP, over the top surface of the semiconductor substrate 1S in the pixel region 1A so as to cover the photodiode PD. The interlayer insulating film IL1 is formed in the peripheral circuit region 2A so as to cover the semiconductor substrate 1S including the gate electrode Glt, and the plugs Pt1 and Pt2 are formed reaching the top surface of the n−type high concentration semiconductor region NR, i.e., the silicide layer SIL formed in the upper layer portion by penetrating the interlayer insulating film IL1.

The interlayer insulating film IL1 is formed from a silicon oxide film whose material is, for example, TEOS (Tetra Ethyl Ortho Silicate). The plugs Pfd, Pt1, and Pt2 are formed by embedding, in a contact hole formed in the interlayer insulating film IL1, for example, a titanium film and a titanium nitride film formed over the titanium film, i.e., a barrier conductor film including a titanium/titanium nitride film and a tungsten film formed over the barrier conductor film.

The plugs, which are not illustrated in FIGS. 5 and 6, are also formed in the interlayer insulating film IL1. Each of the reset transistor RST, the selection transistor SEL, and the amplification transistor AMI, which are not illustrated in FIGS. 5 and 6, also has both a gate electrode formed over the p−type well PWL via a gate insulating film, and a source/drain region formed in the p−type well PWL on both sides of the gate electrode (see FIG. 2). Because the selection transistor SEL and the amplification transistor AMI are coupled in series, they share the source/drain region between them (see FIG. 2).

For example, an interlayer insulating film IL2 is formed over the interlayer insulating film IL1 in the pixel region 1A and the peripheral circuit region 2A, and the wiring M1 is formed in the interlayer insulating film IL2. The interlayer insulating film IL2 is formed, for example, from a silicon oxide film, but it is not limited thereto, and the interlayer insulating film IL2 may be formed from a low dielectric constant film having a dielectric constant lower than that of a silicon oxide film. The low dielectric constant films include, for example, an SiOC film. The wiring M1 is formed, for example, from copper (Cu) wiring and can be formed by using a damascene process. As described in the variation that will be described later, the wiring M1 can also be formed from aluminum (Al) wiring without limiting to Cu wiring.

When the wiring M1 includes, for example, Cu wiring, a liner film LF1, including an insulating film such as, for example, a silicon carbonitride (SiCN) film, is formed over the interlayer insulating film IL2. The liner film LF1 is a diffusion preventing film for preventing diffusion of the wiring M1 including, for example, Cu wiring. The liner film LF1 is also a protective film for protecting the interlayer insulating film IL2.

An interlayer insulating film IL3, including, for example, a silicon oxide film or a low dielectric constant film, is formed over the liner film LF1, and wiring M2 including, for example, Cu wiring, is formed in the interlayer insulating film IL3. When the wiring M2 includes, for example, Cu wiring, a liner film LF2, including an insulating film such as, for example, an SiCN film, is formed over the interlayer insulating film IL3. The liner film LF2 is a diffusion preventing film for preventing diffusion of the wiring M2 including, for example, Cu wiring. The liner film LF2 is a protective film for protecting the interlayer insulating film IL3.

An interlayer insulating film IL4, including, for example, a silicon oxide film or a low dielectric constant film, is formed over the liner film LF2, and wiring M3, including, for example, Cu wiring, is formed in the interlayer insulating film IL4. When the wiring M3 includes, for example, Cu wiring, a liner film LF3, including an insulating film such as, for example, an SiCN film, is formed over the interlayer insulating film IL4. The liner film LF3 is a diffusion preventing film for preventing diffusion of the wiring M3 including, for example, Cu wiring. The liner film LF3 is also a protective film for protecting the interlayer insulating film IL4. An interlayer insulating film IL5, including, for example, a silicon oxide film or a low dielectric constant film, is formed over the liner film LF3.

Thus, a wiring layer WL1 (see FIG. 6) is formed by a plurality of the wiring M1 to M3 formed in each of a plurality of the interlayer insulating films IL2 to IL4, respectively, of a plurality of the interlayer insulating films IL2 to IL5. When the interlayer insulating films IL1 to IL5, the liner films LF1 to LF3, the antireflection film ARF, and the cap insulating film CAP are collectively referred to as an insulating film part IF1, the insulating film part IF1 is formed over a main surface of the semiconductor substrate 1S, i.e., over the top surface thereof so as to cover the photodiode PD. In this case, the insulating film part IF1 includes: the interlayer insulating film IL1; and a laminated insulating film in which each of the interlayer insulating films IL2 to IL4, which serve as a plurality of first insulating layers, and each of the liner films LF1 to LF3, which serve as a plurality of second insulating layers, are alternately laminated. It is preferable that each of the liner films LF1 to LF3 includes a material different from that of any one of the interlayer insulating films IL2 to IL4.

Herein, wiring may not be formed in all of the interlayer insulating films IL2 to IL5, as not formed, for example, in the interlayer insulating film IL5, and the wiring layer WL1 may be formed by wiring formed in some of the interlayer insulating films IL2 to IL5.

In the pixel region 1A, the wiring M1 to M3 are formed not to overlap the photodiode PD in plan view. This is made in order that the light to enter the photodiode PD is not blocked by the wiring M1 to M3.

In the pixel region 1A, a concave portion CC1, which reaches the antireflection film ARF by penetrating, for example, the interlayer insulating films IL1 to IL5 and the liner films LF1 to LF3, is formed in the interlayer insulating films IL1 to IL5 and the liner films LF1 to LF3. The concave portion CC1 is formed to overlap the center CP of the photodiode PD in plan view. When the interlayer insulating films IL1 to IL5, the liner films LF1 to LF3, the antireflection film ARF, and the cap insulating film CAP are collectively referred to as the insulating film part IF1, as described above, the concave portion CC1 is therefore formed in the upper surface of the insulating film part IF1 in a portion that overlaps the center CP of the photodiode PD in plan view.

In the specification of the present application, the center of the photodiode PD in plan view means the center of gravity of the photodiode PD in plan view.

In the example illustrated in FIG. 5, the concave portion CC1 is formed to reach the upper surface of the antireflection film ARF by penetrating the interlayer insulating films IL1 to IL5 and the liner films LF1 to LF3. That is, the concave portion CC1 is formed to extend from the upper surface of the insulating film part IF1 to the middle thereof. Alternatively, the concave portion CC1 may be formed to reach the interlayer insulating film IL1 by penetrating a laminated insulating film including, for example, the interlayer insulating film IL5, the liner film LF3, the interlayer insulating film IL4, the liner film LF2, the interlayer insulating film IL3, the liner film LF1, and the interlayer insulating film IL2.

In the pixel region 1A and the peripheral circuit region 2A, a transmission film TF1, including, for example, a silicon oxide film or a low dielectric constant film, is formed over the interlayer insulating film IL5.

The transmission film TF1 transmits the incident light to enter the photodiode PD in the pixel region 1A. The transmission film TF1 is also a transmission film part formed over the interlayer insulating film IL5, i.e., over the insulating film part IF1 so as to close the concave portion CC1. The thickness of the transmission film TF1 is, for example, 100 to 500 nm. When the transmission film TF1 includes, for example, a silicon oxide film or a low dielectric constant film, the transmittance of the transmission film TF1 to visible light can be improved.

A hollow space SP1 is formed by the concave portion CC1 and the transmission film TF1. As described above, the concave portion CC1 is formed in the upper surface of the insulating film part IF1 in a portion that overlaps the center CP of the photodiode PD in plan view. Accordingly, the space SP1 is arranged to overlap the center CP of the photodiode PD in plan view.

The space SP1 is a hollow optical waveguide WG1 by which incident light is guided to the photodiode PD. That is, the light that has passed through the transmission film TF1 enters the photodiode PD after passing through the space SP1 as the hollow optical waveguide WG1. Accordingly, the incident light, which has passed through the transmission film TF1 and entered the optical waveguide WG1, can be guided to the photodiode PD without being attenuated.

In the peripheral circuit region 2A, a plug Pt3, which reaches the wiring M3 formed in the interlayer insulating film IL4 by penetrating the transmission film TF1, the interlayer insulating film IL5, and the liner film LF3, is formed. In the peripheral circuit region 2A, an electrode pad EP1 is formed over the transmission film TF1, and the electrode pad EP1 is electrically coupled to the plug Pt3.

In the pixel region 1A and the peripheral circuit region 2A, a protective film PF1, including, for example, a silicon nitride film, is formed over the transmission film TF1.

In the pixel region 1A, an opening OP1, which reaches the transmission film TF1 by penetrating the protective film PF1, is formed in the protective film PF1 in a portion located above the concave portion CC1. A color filter layer CF is formed in the opening OP1. That is, the color filter layer CF is formed over the transmission film TF1 in a portion located above the concave portion CC1.

The color filter layer CF is a film that transmits the light having specific colors such as, for example, red (R), green (G), and blue (B), and does not transmit the light having other colors. In other words, the color filter layer CF is a film that transmits the light having wavelengths within a specific range and does not transmit the light having other wavelengths. Accordingly, the color filter layer CF includes films colored, for example, in each of red (R), green (G), and blue (B).

In the peripheral circuit region 2A, the protective film PF1 is formed over the transmission film TF1 so as to cover the electrode pad EP1. An opening OP2, which reaches the electrode pad EP1 by penetrating the protective film PF1, is formed in the protective film PF1 over the electrode pad EP1, and the electrode pad EP1 is exposed at the bottom of the opening OP2.

In the pixel region 1A, a micro lens ML whose upper surface is convex is formed over the color filter layer CF. The micro lens ML is a convex lens whose upper surface is curved, and includes a film that transmits light.

When light is radiated onto the pixel PU (see FIG. 1) in FIG. 5, incident light first passes through the micro lens ML. Thereafter, the light passes through the color filter layer CF and the transmission film TF1, and then enters the antireflection film ARF after passing through the space SP1 serving as the hollow optical waveguide WG1. In the antireflection film ARF, a sufficient amount of the incident light enters the photodiode PD by controlling the reflection of the incident light.

In the photodiode PD, the energy of the incident light is larger than the bandgap of silicon, and hence the incident light is absorbed to generate a hole-electron pair by photoelectric conversion. The electron generated at the time is accumulated in the n−type well NWL. Then, the transfer transistor TX is turned on at an appropriate timing. Specifically, a voltage, which is larger than or equal to a threshold voltage, is applied to the gate electrode of the transfer transistor TX. Then, a channel region is formed in a channel formation region immediately below the gate insulating film, thereby the n−type well NWL, serving as the source region of the transfer transistor TX, and the n−type high concentration semiconductor region NR, serving as the drain region of the transfer transistor TX, are electrically conducted together. As a result, the electrons accumulated in the n−type well NWL reach the drain region after passing through the channel region, and pass from the drain region to the wiring layer to be taken out into an external circuit.

The silicide layer SIL may be formed in the top surface of the n−type high concentration semiconductor region NR, serving as the drain region of the transfer transistor, i.e., in the upper layer portion. Thereby, the coupling resistance between the n−type high concentration semiconductor region NR and the plug Pfd can be reduced.

<Arrangement of Hollow Optical Waveguide>

Subsequently, arrangement of the hollow optical waveguide in plan view will be described. In a semiconductor device including a high-sensitive CMOS image sensor such as, for example, a CMOS image sensor for a single-lens reflex camera, the length of one side of a pixel exceeds 1 μm having a rectangular shape is, for example, approximately 2 to 4 μm in plan view. Hereinafter, the case where the length of one side of a pixel exceeds 1 μm will be exemplified for description.

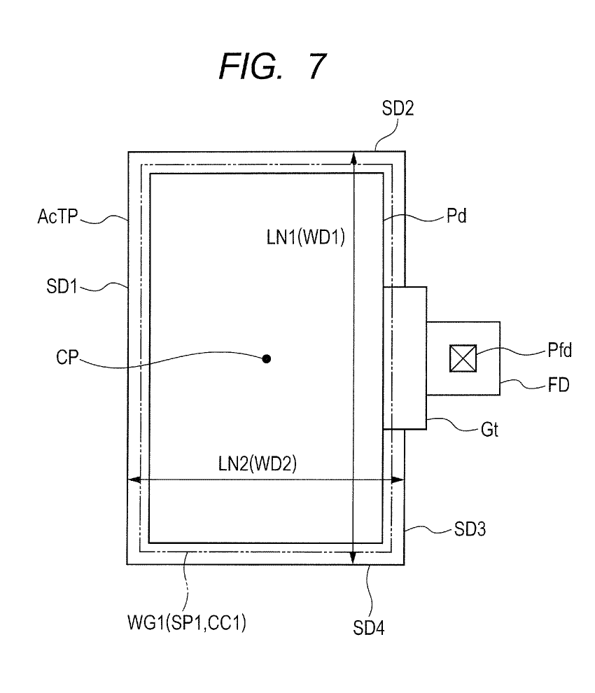

FIG. 7 is a plan view illustrating an example of the pixel of the semiconductor device of First Embodiment. In the example illustrated in FIG. 7, the active region AcTP has a rectangular shape in plan view, the active region AcTP having: a side SD1; a side SD2 intersecting with the side SD1; a side SD3 facing the side SD1; and a side SD4 facing the side SD2.

The space SP1 serving as the hollow optical waveguide WG1, i.e., the concave portion CC1 is formed in the upper surface of the insulating filmpart IF1 (see FIG. 5) in a portion that overlaps the center CP of the photodiode PD in plan view. Thereby, the light, which has passed through the micro lens ML (see FIG. 5) and the color filter layer CF (see FIG. 5), enters at least a central portion of the photodiode PD in plan view after passing through the hollow optical waveguide WG1. Accordingly, the light, which has passed through the micro lens ML and the color filter layer CF, is not attenuated before entering the central portion of the photodiode PD, and hence the sensitivity of the CMOS image sensor can be improved.

The concave portion CC1 is preferably formed, in plan view, in the region where the photodiode PD is formed. In this case, the space SP1, serving as the hollow optical waveguide WG1, is arranged, in plan view, in the region where the photodiode PD is formed. There is the fear that: a dark current, which is a current flowing even in a state where light is not radiated, may be generated in an outer periphery of the photodiode PD in plan view due to, for example, the presence of a crystal defect, etc.; and an image to be captured may be degraded. Accordingly, by arranging, in plan view, the hollow optical waveguide WG1 in the region where the photodiode PD is formed, light is hardly radiated onto the outer periphery of the photodiode PD in plan view, thereby enabling a dark current to be reduced.

Herein, the case will be considered, in which the position of the outer periphery of the photodiode PD in plan view and the position of the outer periphery of the hollow optical waveguide WG1 in plan view are the same as the position of the outer periphery of the active region AcTP in plan view. Also, it is assumed that: the length of each of the sides SD1 and SD3 of the active region AcTP is a length LN1; and the length of each of the sides SD2 and SD4 thereof is a length LN2. In this case, a width WD1 of the hollow optical waveguide WG1, in the direction along the sides SD1 and SD3, is almost the same as the length LN1 of each of the sides SD1 and SD3 of the active region AcTP; and a width WD2 of the hollow optical waveguide WG1, in the direction along the sides SD2 and SD4, is almost the same as the length LN2 of each of the sides SD2 and SD4 thereof.

In the example illustrated in FIG. 7, it is assumed, for example, that: the length LN1 is 3.2 μm; the length LN2 is 2.4 μm; the width WD1 is equal to the length LN1; the width WD2 is equal to the length LN2; and a depth DP1 of the hollow optical waveguide WG1 (see FIG. 5) is 3.5 to 3.9 μm. In this case, an aspect ratio RT1, which is a ratio of the depth DP1 of the hollow optical waveguide WG1 to the width WD1 or the width WD2 thereof, becomes 1.1 to 1.6. Alternatively, it is assumed, for example, that: the length LN1 is 5.7 μm; the length LN2 is 4 μm; the width WD1 is equal to the length LN1; the width WD2 is equal to the length LN2; and the depth DP1 of the hollow optical waveguide WG1 is 4.3 μm. In this case, the aspect ratio RT1, which is a ratio of the depth DP1 of the hollow optical waveguide WG1 to the width WD1 or the width WD2 thereof, becomes 1.1 or 0.75.

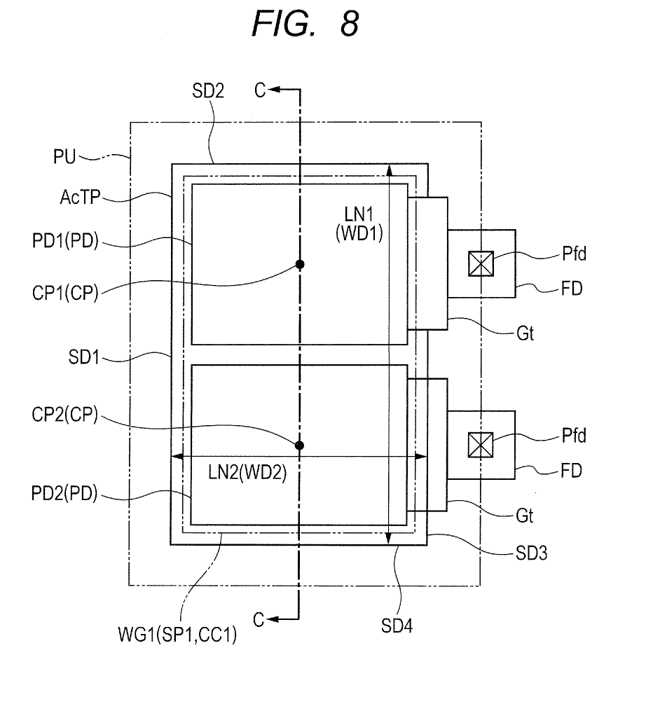

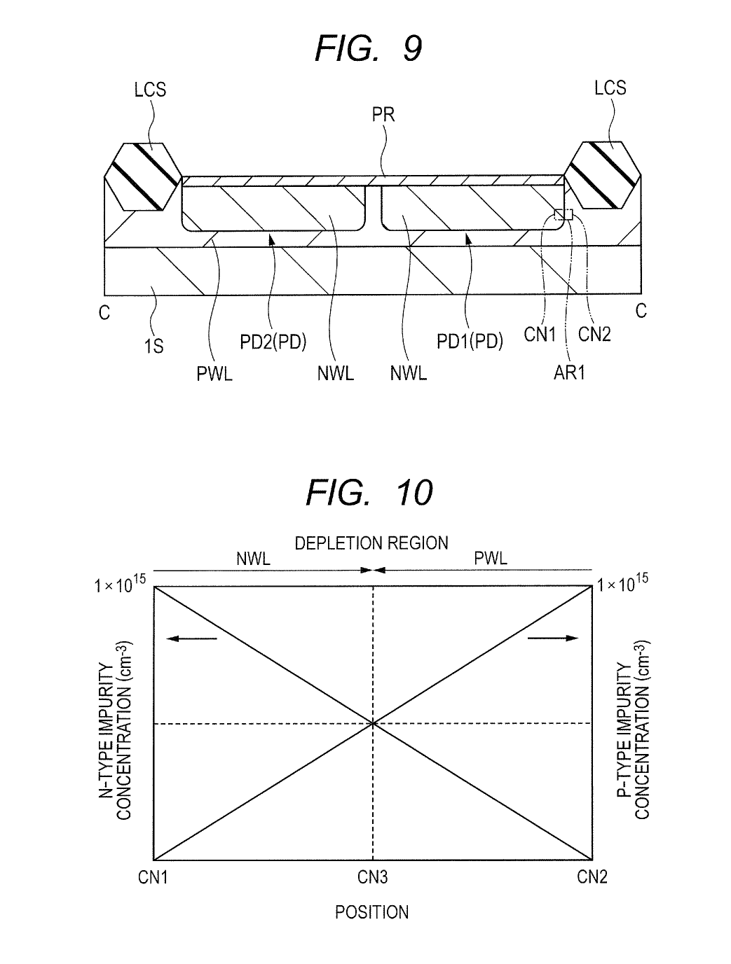

FIG. 8 is a plan view illustrating another example of the pixel of the semiconductor device of First Embodiment. FIG. 9 is a sectional view illustrating another example of the pixel of the semiconductor device of First Embodiment. FIG. 9 is a sectional view, taken along C-C Line in FIG. 8. In FIG. 9, illustration of the cap insulating film CAP (see FIG. 5) and portions located above the cap insulating film CAP is omitted.

Also in the example illustrated in FIG. 8, the active region AcTP has a rectangular shape in plan view, similarly to the example illustrated in FIG. 7, the active region AcTP having: a side SD1; a side SD2 intersecting with the side SD1; a side SD3 facing the side SD1; and a side SD4 facing the side SD2.

On the other hand, two photodiodes PD1 and PD2, as the photodiode PD, are arranged in one active region AcTP so as to be spaced apart from each other in plan view, in the example illustrated in FIG. 8. In such a case, one pixel PU is formed in one active region AcTP, but the one pixel PU includes two photodiodes PD1 and PD2.

In the example illustrated in FIG. 8, the space SP1 as the hollow optical waveguide WG1, i.e., the concave portion CC1 is formed in the upper surface of the insulating film part IF1 (see FIG. 5) in a portion that overlaps both a center CP1, as the center CP of the photodiode PD1, and a center CP2, as the center CP of the photodiode PD2, in plan view. Thereby, the light, which has passed through the micro lens ML (see FIG. 5) and the color filter layer CF (see FIG. 5), enters both at least a central portion of the photodiode PD1 in plan view and at least a central portion of the photodiode PD2 in plan view after passing through the hollow optical waveguide WG1. Accordingly, the light, which has passed through the micro lens ML and the color filter layer CF, is not attenuated before entering each of the central portions of the photodiodes PD1 and PD2, and hence the sensitivity of the CMOS image sensor can be improved.

In the example illustrated in FIG. 8, it is assumed, for example, that: the length LN1 is 3.2 μm; the length LN2 is 2.4 μm; the width WD1 is equal to the length LN1; the width WD2 is equal to the length LN2; and the depth DP1 of the hollow optical waveguide WG1 (see FIG. 5) is 3.5 to 3.9 μm. In this case, an aspect ratio RT1, which is a ratio of the depth DP1 of the hollow optical waveguide WG1 to the width WD1 or the width WD2 thereof, becomes 1.1 to 1.6.

FIG. 10 is a graph schematically showing changes in impurity concentration at the boundary between the n−type well and the p−type well. FIG. 10 shows changes in impurity concentration in the region AR1 illustrated in FIG. 9.

In the specification of the present application, the outer periphery of the photodiode PD in plan view is defined as the boundary between the n−type well NWL and the p−type well PWL. Also, the boundary between the n−type well NWL and the p−type well PWL is defined as a position where an n−type impurity concentration and a p−type impurity concentration are equal to each other.

As shown in FIG. 10, a position of the n−type well NWL, where the lower limit of a range in which an n−type impurity concentration can be detected is, for example, 1×10¹⁵ cm⁻³, is set to be a position CN1. Similarly, a position of the p−type well PWL, where the lower limit of a range in which a p−type impurity concentration can be detected is, for example, 1×10¹⁵ cm⁻³, is set to be a position CN2. In such a case, a position CN3, where an n−type impurity concentration and a p−type impurity concentration become equal to each other, is located between the positions CN1 and CN2.

The positions CN1 and CN2 can be determined by measuring distribution of the impurity concentrations in the section of the semiconductor device illustrated in FIG. 5 with the use, for example, of a Scanning Capacitance Microscopy (SCN). Thereby, for example, the middle position between the positions CN1 and CN2 can be determined as the position CN3.

<Manufacturing Method of Semiconductor Device>

Subsequently, a manufacturing method of the semiconductor device of First Embodiment will be described.

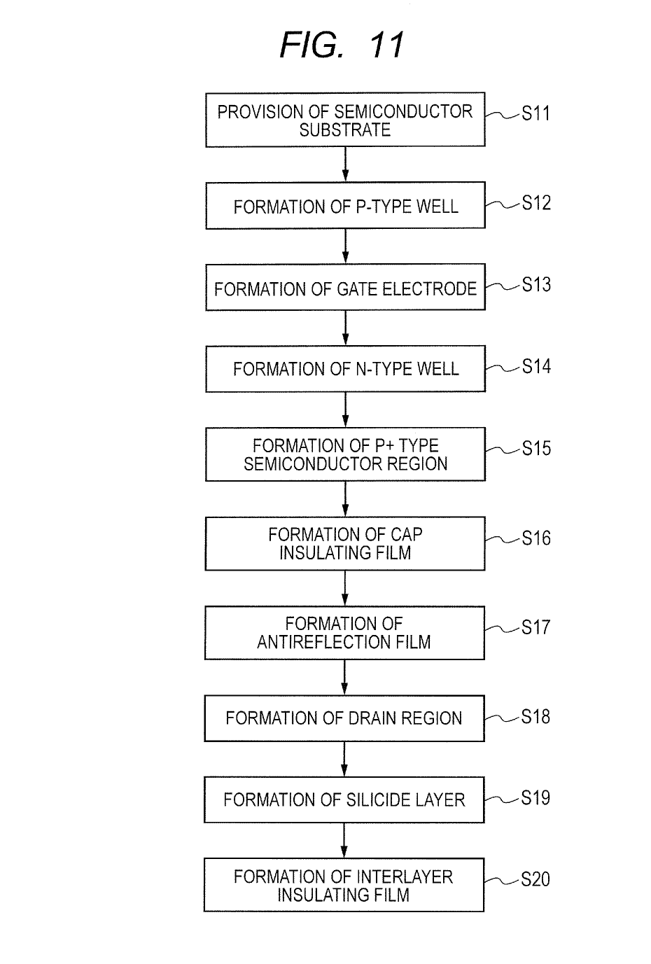

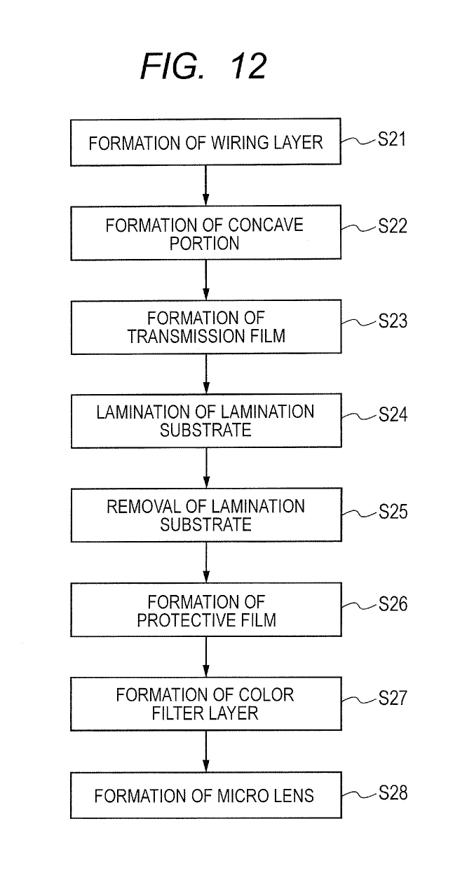

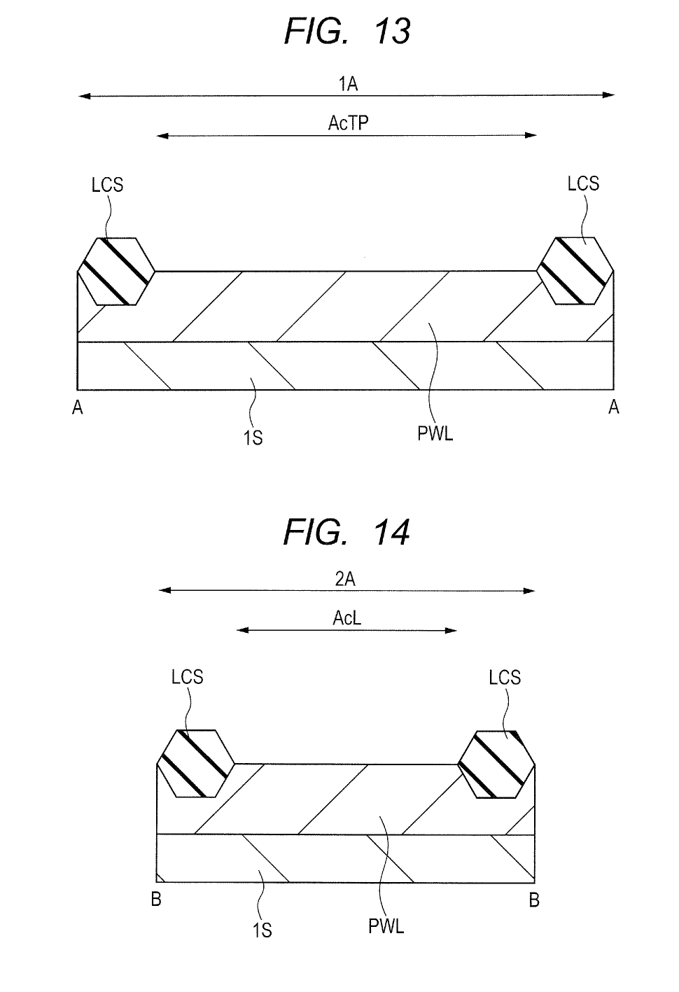

FIGS. 11 and 12 are manufacturing process flow charts each illustrating part of manufacturing steps of the semiconductor device of First Embodiment. FIGS. 13 to 28 are sectional views each illustrating a manufacturing step of the semiconductor device of First Embodiment. Herein, FIGS. 11 and 12 illustrate, of the manufacturing steps of the semiconductor device of First Embodiment, mainly the manufacturing steps in the pixel region 1A. Each of the sectional views of FIGS. 13 to 28 corresponds to the A-A section in FIG. 5 or the B-B section in FIG. 6.

As illustrated in FIGS. 13 and 14, an n−type single crystal silicon substrate, including n−type impurities such as, for example, phosphorus (P) or arsenic (As), is provided as the semiconductor substrate 1S (Step S11 in FIG. 11).

Subsequently, the element isolation region LCS is formed in the semiconductor substrate 1S. The element isolation region LCS includes a thermally-oxidized film. The element isolation region LCS, including an insulating member such as a silicon oxide film, is formed, for example, by covering, of the semiconductor substrates 1S, a region that is to serve as active regions such as the active region AcTP and the active region AcL, with a silicon nitride film and then by subjecting to thermal oxidation. Such an element isolation method is referred to as a LOCOS (Local oxidation of silicon) method. The active regions, such as the active region AcTP and the active region AcL, are divided, i.e., formed by this element isolation region LCS.

Herein, the active region AcTP is formed in the pixel region 1A, and the active region AcL is formed in the peripheral circuit region 2A.

The element isolation region may be formed by using an STI (Shallow Trench Isolation) method, instead of the LOCOS method. In this case, the element isolation region includes an insulating member embedded in a trench in the semiconductor substrate 1S. The isolation trench is formed by etching the semiconductor substrate 1S with the use, for example, of the aforementioned silicon nitride film as a mask. Subsequently, the element isolation region is formed by embedding an insulating film, such as a silicon oxide film, in the isolation trench.

Subsequently, as illustrated in FIGS. 13 and 14, the p−type well PWL is formed in the pixel region 1A and the peripheral circuit region 2A (Step S12 in FIG. 11).

In Step S12, p−type impurities, such as boron (B), are introduced into the semiconductor substrate 1S in the active regions AcTP and AcL by using a photolithography technique and an ion implantation method. Thereby, the p−type well PWL is formed in the pixel region 1A and the peripheral circuit region 2A. The conductivity type of the p−type well PWL is a p−type, which is opposite to an n−type that is the conductivity type of the semiconductor substrate 1S.

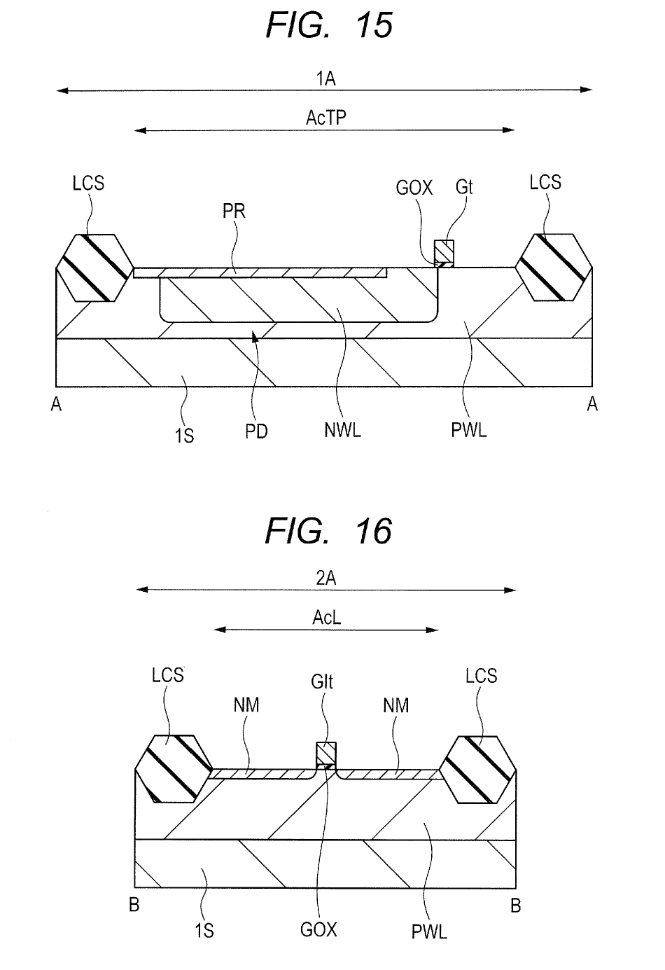

Subsequently, as illustrated in FIGS. 15 and 16, the gate electrode Gt is formed in the pixel region 1A via the gate insulating film GOX, and the gate electrode Glt is formed in the peripheral circuit region 2A via the gate insulating film GOX (Step S13 in FIG. 11).

In the pixel region 1A and the peripheral circuit region 2A, the gate insulating film GOX including a silicon oxide film is first formed in the top surface of the p−type well PWL by subjecting the semiconductor substrate 1S to thermal oxidation. A silicon nitride film, a silicon oxynitride film, or the like may be used as the gate insulating film GOX. Alternatively, a so-called high dielectric film such as a hafnium-based insulating film formed by introducing lanthanum oxide into hafnium oxide, that is, a film having a dielectric constant higher than that of a silicon nitride film may be used. These films can be formed by using, for example, a CVD (Chemical Vapor Deposition) method.

The thickness of the gate insulating film in the pixel region 1 may be made different from that of the gate insulating film in the peripheral circuit region 2A. In this case, the operation speed of a peripheral circuit can be improved by making the gate insulating film in the peripheral circuit region 2A thinner than that in the pixel region 1A, which is achieved by: oxidizing the semiconductor substrate 1S in the pixel region 1A and the peripheral circuit region 2A; thereafter, removing an oxide film in the peripheral circuit region 2A; and then oxidizing the semiconductor substrate 1S in the pixel region 1A and the peripheral circuit region 2A.

Subsequently, for example, a polycrystalline silicon film is formed as a conducting film over the semiconductor substrate 1S including the gate insulating film GOX by using a CVD method, etc. The conducting film is then patterned. Specifically, a photoresist film, i.e., a resist film (not illustrated) is formed over the conducting film, and then is exposed and developed by using a photolithography technique, thereby allowing the photoresist film to be left in the regions where the gate electrodes Gt and Glt are to be formed. Subsequently, the conducting film and the silicon oxide film are etched by using the resist film as a mask. Thereby, the gate electrode Gt including the conducting film is formed in the pixel region 1A via the gate insulating film GOX including the silicon oxide film, and the gate electrode Glt including the conducting film is formed in the peripheral circuit region 2A via the gate insulating film GOX including the silicon oxide film. Subsequently, the resist film is removed by asking, etc. Such steps including from the formation of a resist film to the removal thereof are referred to as patterning. At the time, the gate electrode Gr, the gate electrode Gs, and the gate electrode Ga of the other transistors illustrated, for example, in FIG. 2, that is, of the reset transistor RST, the selection transistor SEL, and the amplification transistor AMI, may be formed.

Subsequently, as illustrated in FIGS. 15 and 16, the n−type well NWL is formed in the pixel region 1A so as to be included in the p−type well PWL on one side of the gate electrode Gt (left side in FIG. 15) (Step S14 in FIG. 11).

N−type impurity ions are ion-implanted by using, for example, the resist film (not illustrated), which is opened on the one side of the gate electrode Gt, as a mask. Thereby, the n−type well NWL included in the p−type well PWL is formed, as illustrated in FIG. 15. The photodiode PD is formed by the p−type well PWL and the n−type well NWL. Part of the n−type well NWL is formed to overlap the gate electrode Gt of the transfer transistor in plan view. The n−type well NWL can also be caused to function as the source region of the transfer transistor by thus overlapping part of the n−type well NWL with the gate electrode Gt of the transfer transistor.

Subsequently, as illustrated in FIGS. 15 and 16, the p+ type semiconductor region PR is formed in the top surface region of the n−type well NWL in the pixel region 1A (Step S15 in FIG. 11). P−type impurity ions are ion-implanted into the top surface region of the n−type well NWL by using, for example, a photolithography technique and an ion implantation method. Thereby, the p+ type semiconductor region PR is formed in the top surface region of the n−type well NWL, as illustrated in FIG. 15.

Subsequently, as illustrated in FIGS. 15 and 16, the n−type low concentration semiconductor region NM is formed in the p−type well PWL on both sides of the gate electrode Glt in the peripheral circuit region 2A. For example, n−type impurity ions are ion-implanted by using, both the resist film (not illustrated), in which the peripheral circuit region 2A is opened, and the gate electrode Glt as a mask. Thereby, the n−type low concentration semiconductor region NM is formed in the p−type well PWL on both sides of the gate electrode Glt.

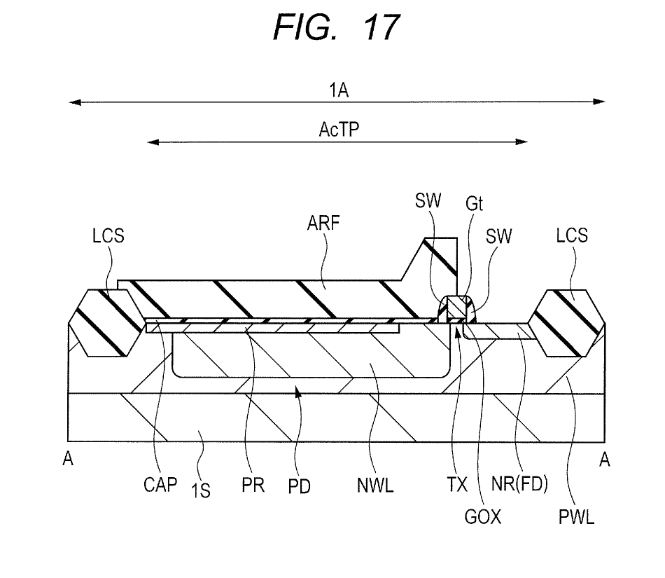

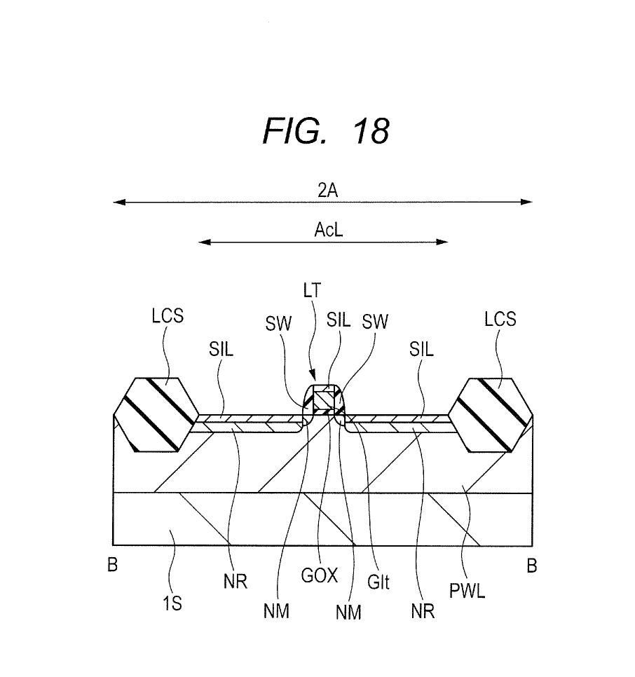

Subsequently, as illustrated in FIGS. 17 and 18, the cap insulating film CAP is formed in the pixel region 1A (Step S16 in FIG. 11).

The sidewall SW including an insulating film is first formed in the sidewalls of the gate electrodes Gt and Glt. For example, a silicon oxide film, a silicon nitride film, or a laminated film including them is deposited, as an insulating film, over the semiconductor substrate 1S by using a CVD method, etc., and then the insulating film is anisotropically etched by using an RIE (Reactive Ion Etching) method, etc. Thereby, the sidewall SW including an insulating film can be left in the sidewalls of the gate electrodes Gt and Glt.

After the sidewall SW is thus formed, the cap insulating film CAP is formed in the pixel region 1A. A silicon oxide film is formed, as an insulating film, over the semiconductor substrate 1S by using, for example, a CVD method, etc., and then the insulating film is patterned. Thereby, the cap insulating film CAP including the silicon oxide film is formed in the top surface regions of both the n−type well NWL on the one side of the gate electrode Gt and the p+ type semiconductor region PR, in the pixel region 1A. Alternatively, a silicon nitride film may be used as an insulating film that forms the cap insulating film CAP, instead of the silicon oxide film.

In the aforementioned flow, the cap insulating film CAP and the antireflection film ARF are formed after the sidewall SW is formed. However, the antireflection film ARF may be formed by etching using an RIE method with the use of the resist pattern formed over the photodiode PD as a mask, at the time when the sidewall SW is formed. In this case, the cap insulating film CAP, the gate insulating film GOX, and the antireflection film ARF include the same material as that of the sidewall SW.

Subsequently, as illustrated in FIGS. 17 and 18, the antireflection film ARF is formed in the pixel region 1A (Step S17 in FIG. 11). For example, a silicon oxinitride film is formed as the antireflection film ARF over the semiconductor substrate 1S by a CVD method, etc., and then the silicon oxinitride film is patterned. Thereby, the antireflection film ARF is formed over the cap insulating film CAP on the one side of the gate electrode Gt.

Subsequently, as illustrated in FIGS. 17 and 18, the n−type high concentration semiconductor region NR is formed in the p−type well PWL on the other side of the gate electrode Gt (right side in FIG. 17) in the pixel region 1A (Step S18 in FIG. 11). N−type impurity ions are ion-implanted by using, for example, the antireflection film ARF and the gate electrode Gt as a mask. Thereby, the n−type high concentration semiconductor region NR is formed in the p−type well PWL on the other side of the gate electrode Gt (right side in FIG. 17) of the transfer transistor TX, as illustrated in FIG. 17. The n−type high concentration semiconductor region NR is also the drain region of the transfer transistor TX, and is also a semiconductor region serving as the floating diffusion FD of the photodiode PD.

In Step S18, it is preferable to form the n−type high concentration semiconductor region NR in the p−type well PWL on both sides of a composite body, formed by the gate electrode Glt and the sidewall SW, in the peripheral circuit region 2A. N−type impurity ions are ion-implanted by using, for example, the gate electrode Glt and the sidewall SW as a mask. Thereby, the source/drain region of the transistor LT, i.e., a source/drain region having an LDD structure including both the n−type low concentration semiconductor region NM and the n−type high concentration semiconductor region NR, can be formed, as illustrated in FIG. 18.

Herein, the source/drain regions of the other transistors illustrated, for example, in FIG. 2, that is, of the reset transistor RST, the selection transistor SEL, and the amplification transistor AMI may be formed by using Step S18.

When a p−type MISFET is formed in the peripheral circuit region 2A, a p−type high concentration semiconductor region, which is to serve as the source/drain region of the p−type MISFET, may be formed in the peripheral circuit region 2A. P−type impurity ions are ion-implanted, for example, into the n−type well on both sides of the gate electrode of a non-illustrated p−type MISFET in the peripheral circuit region 2A. For example, boron (B) can be used as the p−type impurity ions. In this case, boron may be ion-implanted into the active region AcG.

By the aforementioned steps, the photodiode PD, the transfer transistor TX, and the other transistors not illustrated in FIGS. 17 and 18, that is, the reset transistor RST, the selection transistor SEL, and the amplification transistor AMI are formed in the pixel region 1A of the semiconductor substrate 1S (see FIG. 2). The transistor LT as a MISFET is formed in the peripheral circuit region 2A of the semiconductor substrate 1S.

Subsequently, the silicide layer is formed, as illustrated in FIGS. 17 and 18 (Step S19 in FIG. 11). The silicide layer SIL is formed over the n−type high concentration semiconductor region NR and the gate electrode Glt in the peripheral circuit region 2A, but not formed over the floating diffusion FD in the pixel region 1A. However, the silicide layer may also be formed over the floating diffusion FD.

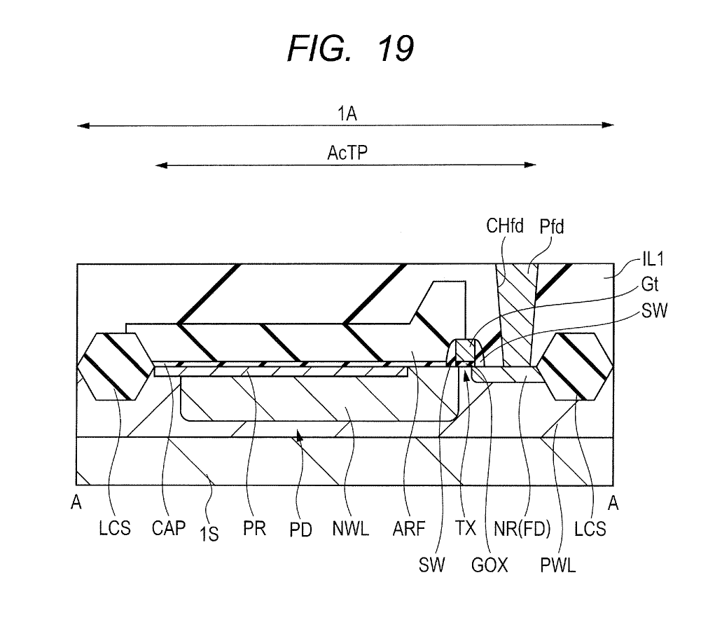

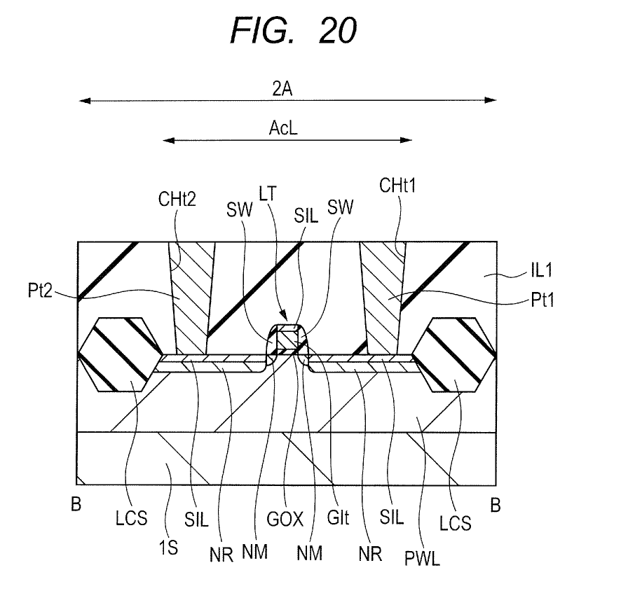

Subsequently, as illustrated in FIGS. 19 and 20, the interlayer insulating film IL1 is formed over the semiconductor substrate 1S in the pixel region 1A and the peripheral circuit region 2A (Step S20 in FIG. 11). In this case, the interlayer insulating film IL1 is formed over the top surface of the semiconductor substrate 1S via the antireflection film ARF and the cap insulating film CAP so as to cover the photodiode PD, in the pixel region 1A.

A silicon oxide film is deposited over the semiconductor substrate 1S, for example, by a CVD method using a TEOS gas as a material gas. Thereafter, the top surface of the interlayer insulating film IL1 is flattened, if necessary, by using a CMP (Chemical Mechanical Polishing) method, etc.

Subsequently, contact holes CHfd, CHt1, and CHt2 are formed by patterning the interlayer insulating film IL1, as illustrated in FIGS. 19 and 20. The contact hole CHfd, which reaches the n−type high concentration semiconductor region NR, as the drain regions of the floating diffusion FD and the transfer transistor TX, by penetrating the interlayer insulating film IL1, is formed above the n−type high concentration semiconductor region NR. Also, the contact holes CHt1 and CHt2, which reach the top surface of the n−type high concentration semiconductor region NR, as the source/drain region of the transistor LT, i.e., the silicide layer SIL formed in the upper layer portion by penetrating the interlayer insulating film IL1, are formed above the n−type high concentration semiconductor region NR as the source/drain region.

In this case, a contact hole is also formed over the gate electrode Gt of the transfer transistor TX. Also in this case, contact holes are formed over the gate electrode Gr, the gate electrode Gs, the gate electrode Ga, and the source/drain regions of the other transistors illustrated, for example, in FIG. 2, that is, of the reset transistor RST, the selection transistor SEL, and the amplification transistor AMI.

Subsequently, the plugs Pfd, pt1, and Pt2 are formed by embedding the conducting films in the contact holes CHfd, CHt1, and CHt2, as illustrated in FIGS. 19 and 20.

The titanium/titanium nitride film is first formed over the interlayer insulating film IL1 including the bottom surface and the side surface of each of the contact holes CHfd, CHt1, and CHt2. The titanium/titanium nitride film is formed by a laminated film including a titanium film and a titanium nitride film located over the titanium film, and can be formed by using, for example, a sputtering method. The titanium/titanium nitride film has a so-called diffusion barrier property by which, for example, tungsten that is a material for a film to be embedded in a later step is prevented from diffusing into silicon.

Then, the tungsten film is formed over the whole main surface of the semiconductor substrate 1S so as to fill the contact holes CHfd, CHt1, and CHt2. This tungsten film can be formed by using, for example, a CVD method. Then, the plugs Pfd, pt1, and Pt2 can be formed by removing the unnecessary titanium/titanium nitride film and the tungsten film formed over the interlayer insulating film IL1 with the use, for example, of a CMP method.

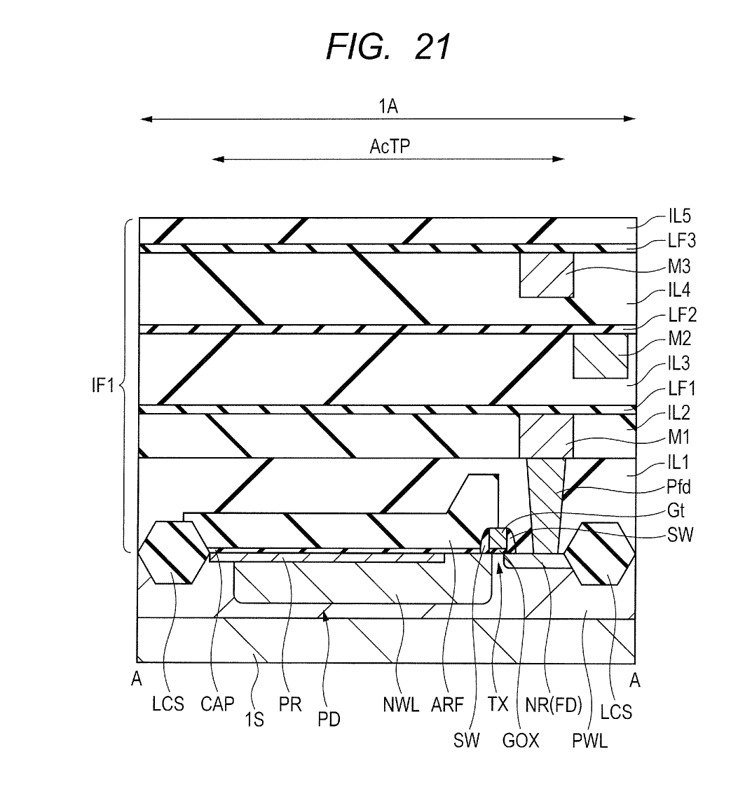

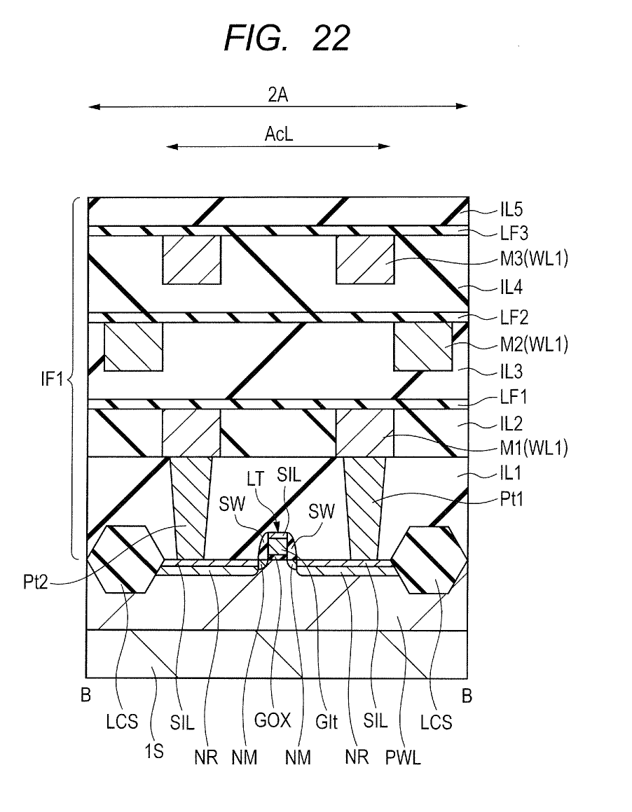

Subsequently, as illustrated in FIGS. 21 and 22, the wiring layer WL1, including the interlayer insulating films IL2 to IL4 and the wiring M1 to M3, is formed over the interlayer insulating film IL1 in the pixel region 1A and the peripheral circuit region 2A (Step S21 in FIG. 12).

The interlayer insulating film IL2, including a low dielectric constant film such as, for example, a silicon oxide film, an SiOC film, or the like, is formed over the interlayer insulating film IL1 by using, for example, a CVD method, etc. Subsequently, the wiring trench is formed by patterning the interlayer insulating film IL2. Subsequently, a laminated film, including a tantalum (Ta) film and a tantalum nitride (TaN) film located over the Ta film, is deposited as a barrier film over the interlayer insulating film IL2 including the inside of the wiring trench by a sputtering method, etc. Subsequently, a thin copper film is deposited as a seed film (not illustrated) over the barrier film by a sputtering method, etc., and a copper film is deposited over the seed film by an electrolytic plating method. Subsequently, the unnecessary barrier film, the seed layer, and the copper film over the interlayer insulating film IL2 are removed by a CMP method, etc. The wiring M1 can be formed by thus embedding the barrier film, the seed film, and the copper film in the wiring trench (single damascene method).

Subsequently, the liner film LF1, including an insulating film such as, for example, a silicon carbonitride (SiCN) film, is formed over the interlayer insulating film IL2 by a CVD method, etc., and the interlayer insulating film IL3, including, for example, a silicon oxide film or a low dielectric constant film, is formed over the liner film LF1 by a CVD method, etc. The liner film LF1 is a diffusion preventing film for preventing diffusion of the wiring M1 including, for example, Cu wiring. The liner film LF1 is also a protective film for protecting the interlayer insulating film IL2. Subsequently, the wiring M2 can be formed in the interlayer insulating film IL3 by the same method as that for the wiring M1.

Subsequently, the liner film LF2, including an insulating film such as, for example, an SiCN film, is formed over the interlayer insulating film IL3 by a CVD method, etc., and the interlayer insulating film IL4, including, for example, a silicon oxide film or a low dielectric constant film, is formed over the liner film LF2 by a CVD method, etc. The liner film LF2 is a diffusion preventing film for preventing diffusion of the wiring M2 including, for example, Cu wiring. The liner film LF2 is also a protective film for protecting the interlayer insulating film IL3. Subsequently, the wiring M3 can be formed in the interlayer insulating film IL4 by the same method as that for the wiring M1.

Subsequently, the liner film LF3, including an insulating film such as, for example, an SiCN film, is formed over the interlayer insulating film IL4 by a CVD method, etc., and the interlayer insulating film IL5, including, for example, a silicon oxide film or a low dielectric constant film, is formed over the liner film LF3 by a CVD method, etc. The liner film LF3 is a diffusion preventing film for preventing diffusion of the wiring

M3 including, for example, Cu wiring. The liner film LF3 is also a protective film for protecting the interlayer insulating film IL4.

Thus, the wiring layer WL1 (see FIG. 22) is formed by the wiring M1 to M3 respectively formed in each of the interlayer insulating films IL2 to IL4, of the interlayer insulating films IL2 to IL5. When the interlayer insulating films IL1 to IL5, the liner films LF1 to LF3, the antireflection film ARF, and the cap insulating film CAP are collectively referred to as the insulating film part IF1, the insulating film part IF1 is formed over a main surface of the semiconductor substrate 1S, i.e., over the top surface thereof so as to cover the photodiode PD, in the pixel region 1A and the peripheral circuit region 2A.

In this case, the step of forming the insulating film part IF1 includes: the step of forming the interlayer insulating film IL1; and the step of forming the laminated insulating film in which each of the interlayer insulating films IL2 to IL4, which serve as the first insulating layers, and each of the liner films LF1 to LF3, which serve as the second insulating layers, are alternately laminated. It is preferable that each of the liner films LF1 to LF3 includes a material different from that of any one of the interlayer insulating films IL2 to IL4.

Herein, wiring may not be formed in all of the interlayer insulating films IL2 to IL5, as not formed, for example, in the interlayer insulating film IL5, and the wiring layer WL1 may be formed by forming wiring in some of the interlayer insulating films IL2 to IL5.

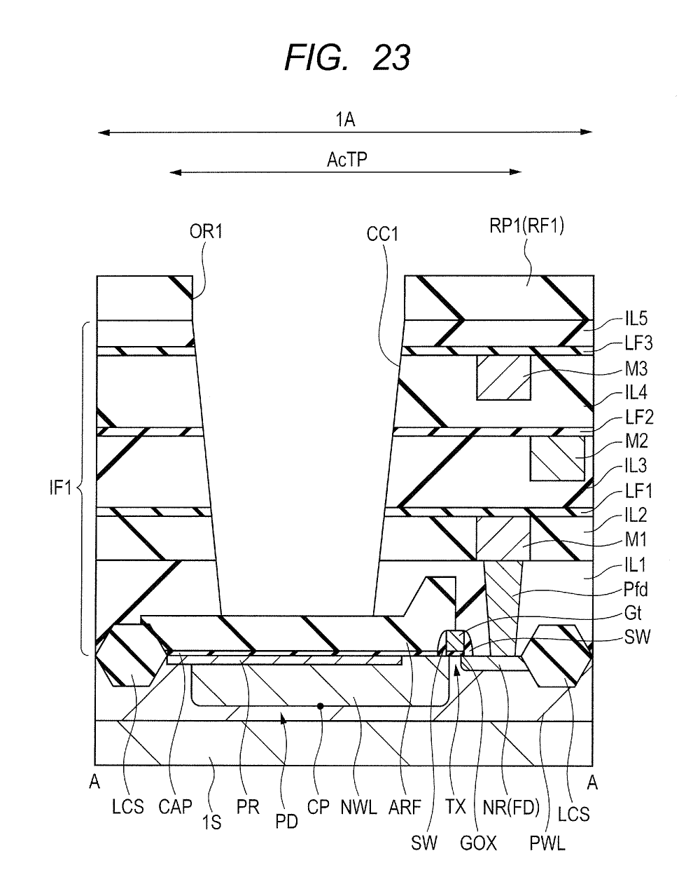

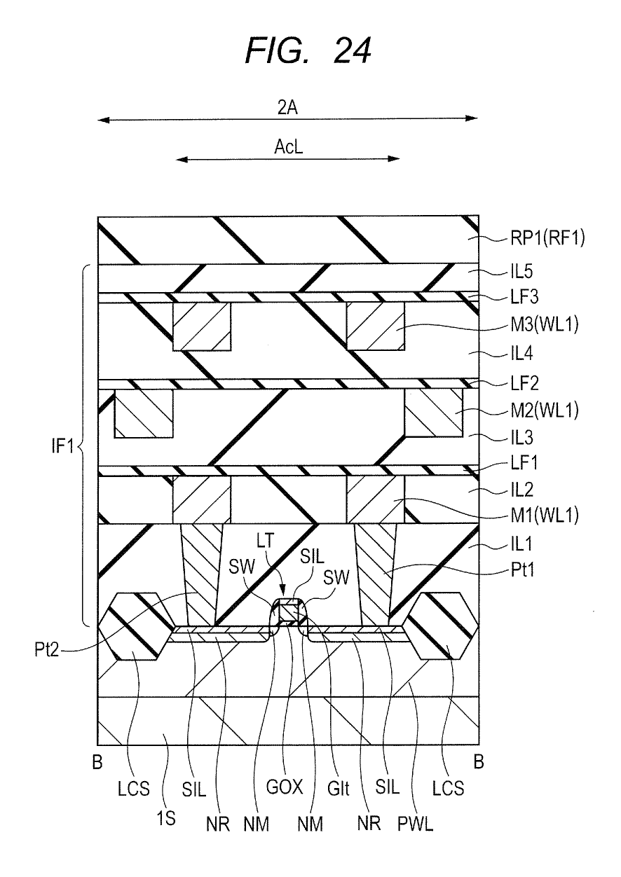

Subsequently, as illustrated in FIGS. 23 and 24, the concave portion CC1 is formed (Step S22 in FIG. 12).

In Step S22, the concave portion CC1, which reaches the antireflection film ARF by penetrating the interlayer insulating films IL1 to IL5 and the liner films LF1 to LF3, is formed in the interlayer insulating films IL1 to IL5 and the liner films LF1 to LF3 in the pixel region 1A. The concave portion CC1 is formed to overlap the center CP of the photodiode PD in plan view. When the interlayer insulating films IL1 to IL5, the liner films LF1 to LF3, the antireflection film ARF, and the cap insulating film CAP are collectively referred to as the insulating film part IF1, as described above, the concave portion CC1 is therefore formed in the upper surface of the insulating film part IF1 in a portion that overlaps the center CP of the photodiode PD in plan view.

Specifically, a resist film RF1 is first formed by applying a resist liquid over the interlayer insulating film IL5, and the formed resist film RF1 is pattern-exposed and developed. Thereby, an opening OR1 is formed, the opening OR1 reaching the interlayer insulating film IL5 in a portion located above the photodiode PD by penetrating the resist film RF1. Then, a resist pattern RP1, including the resist film RF1 in which the opening OR1 is formed, is formed.

Thereafter, both the interlayer insulating film IL5 in a portion exposed at the bottom surface of the opening OR1 of the resist pattern RP1 and the insulating film part IF1 in a portion located below the interlayer insulating film IL5 are etched by using the resist pattern RP1 as a mask. The insulating film part IF1 can be etched by a dry etching method using, for example, an etching gas. Thereby, the concave portion CC1, which reaches the upper surface of the antireflection film ARF by penetrating the interlayer insulating film IL5, the liner film LF3, the interlayer insulating film IL4, the liner film LF2, the interlayer insulating film IL3, the liner film LF1, the interlayer insulating film IL2, and the interlayer insulating film IL1, in a portion located, for example, above the photodiode PD, is formed. Alternatively, the concave portion CC1, which reaches the interlayer insulating film IL1 by penetrating the laminated insulating film including the interlayer insulating film IL5, the liner film LF3, the interlayer insulating film IL4, the liner film LF2, the interlayer insulating film IL3, the liner film LF1, and the interlayer insulating film IL2, may be formed.

The concave portion CC1 is preferably formed, in plan view, in the region where the photodiode PD is formed. Thereby, light is hardly radiated onto the outer periphery of the photodiode PD in plan view, and hence a dark current can be reduced.

When the wiring M1 to M3 include Cu wiring, as described above, the insulating film part IF1 includes the liner films LF1 to LF3. In such a case, if the liner films LF1 to LF3 in a portion located above the photodiode PD are left, incident light is reflected by an interface between any one of the liner films LF1 to LF3, each including a material different from that of each of the interlayer insulating films IL2 to IL5, and any one of the interlayer insulating films IL2 to IL5, thereby causing the incident light to be attenuated. Accordingly, when the concave portion CC1 is not formed in the upper surface of the insulating film part IF1 in a portion located above the photodiode PD and the insulating film part IF1 is left to use as an optical waveguide, the interlayer insulating films IL1 to IL5 can be left, but it is necessary to remove the liner films LF1 to LF3 in a portion located above the photodiode PD. Accordingly, the step of removing each of the liner films LF1 to LF3 in a portion located above the photodiode PD by etching is performed when each of the liner films LF1 to LF3 is formed, which creates the fear that the number of steps in the manufacturing steps of the semiconductor device may be increased.

On the other hand, the concave portion CC1 is formed in the insulating film part IF1 in a portion located above the photodiode PD in First Embodiment, and hence the liner films LF1 to LF3 in a portion located above the photodiode PD can be collectively removed in the step of forming the concave portion CC1. Thereby, the number of steps in the manufacturing steps of the semiconductor device can be reduced.

Although not illustrated, the resist pattern RP1 is then removed by asking using, for example, oxygen plasma.

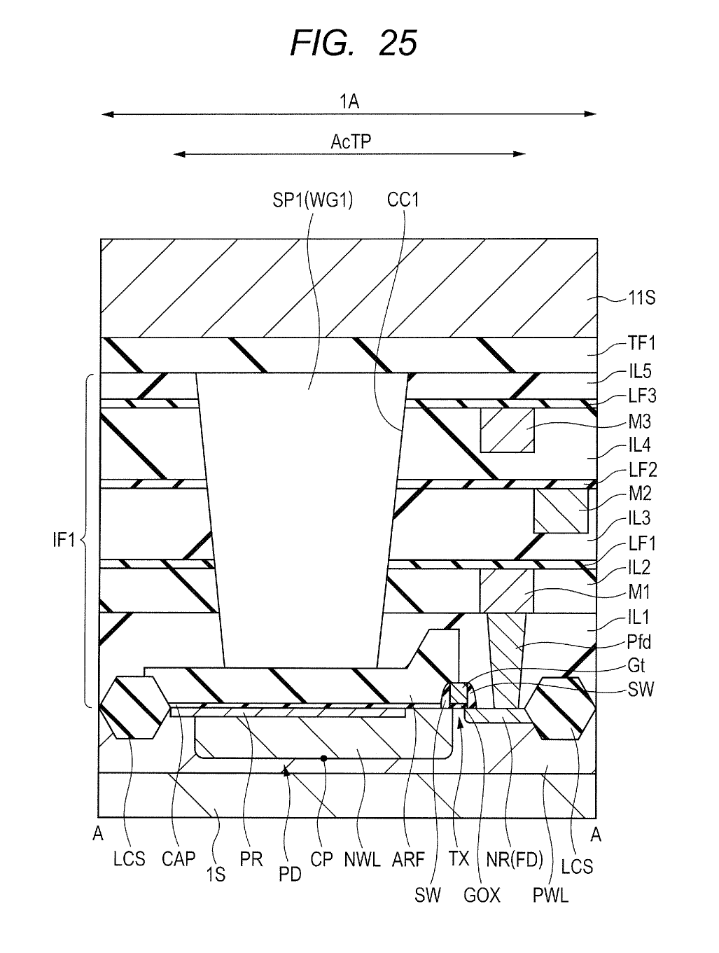

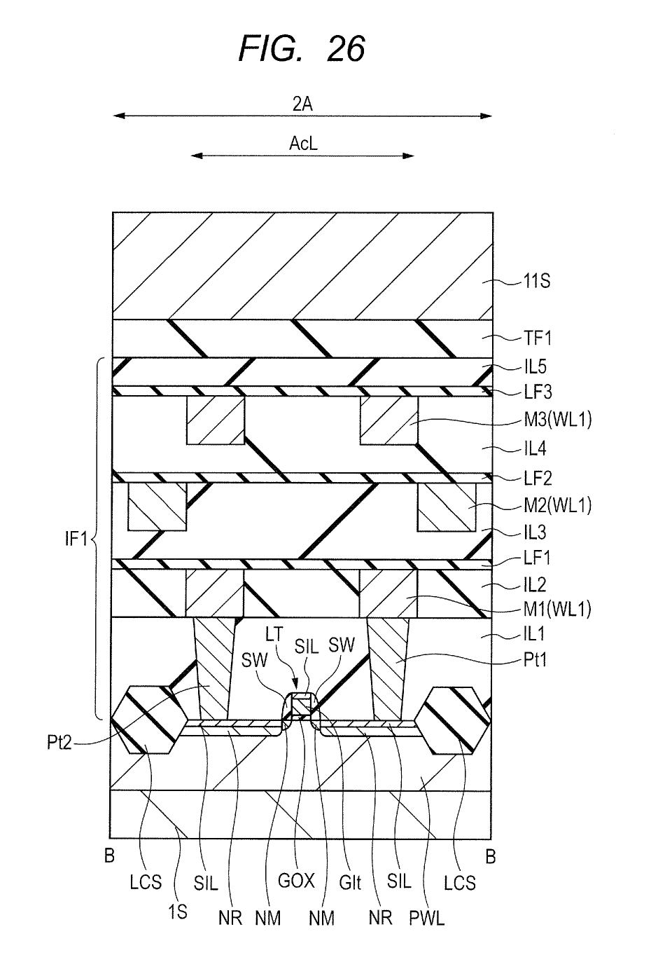

Subsequently, as illustrated in FIGS. 25 and 26, the transmission film TF1 is formed over the top surface of a lamination substrate 11S (Step S23 in FIG. 12).

The lamination substrate 11S including, for example, a semiconductor substrate is first provided, and the transmission film TF1, which includes, for example, a silicon oxide film and transmits visible light, is formed over a main surface of the lamination substrate 11S, i.e., over the top surface thereof by a CVD method, etc., as illustrated in FIGS. 25 and 26. The thickness of the transmission film TF1 can be caused to be, for example, 100 to 500 nm.

Subsequently, as illustrated in FIGS. 25 and 26, the lamination substrate 11S, over the top surface of which the transmission film TF1 is formed, is laminated to the interlayer insulating film IL5 in the pixel region 1A and the peripheral circuit region 2A (Step S24 in FIG. 12).

As illustrated in FIGS. 25 and 26, the lamination substrate 11S is laminated to the semiconductor substrate 1S at low temperature, for example, at normal temperature, in a state where the top surface of the lamination substrate 11S and that of the semiconductor substrate 1S face each other. Subsequently, the semiconductor substrate 1S, to which the lamination substrate 11S has been laminated, is subjected to annealing, i.e., a heat treatment at relatively low temperature, for example, 400° C. or lower, thereby allowing the adhesive force in the interface, i.e., in the joint surface between the transmission film TF1 of the lamination substrate 11S and the interlayer insulating film IL5 of the semiconductor substrate 1S to be increased. Thereby, the transmission film TF1 formed over the top surface of the lamination substrate 11S and the interlayer insulating film IL5 formed over the top surface of the semiconductor substrate 1S are joined together. That is, the transmission film TF1 formed over the top surface of the lamination substrate 11S and the insulating film part IF1 formed over the top surface of the semiconductor substrate 1S are joined together.

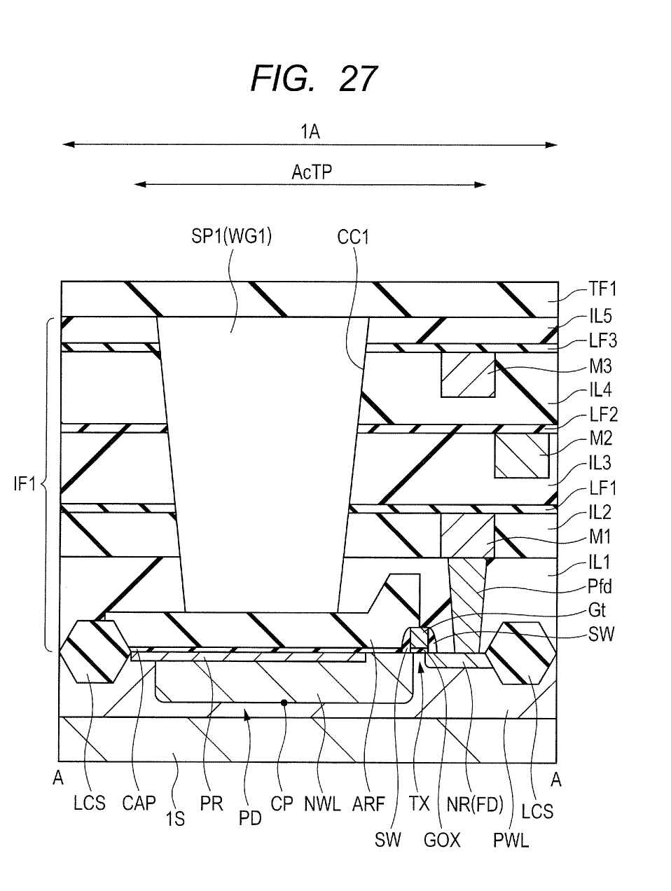

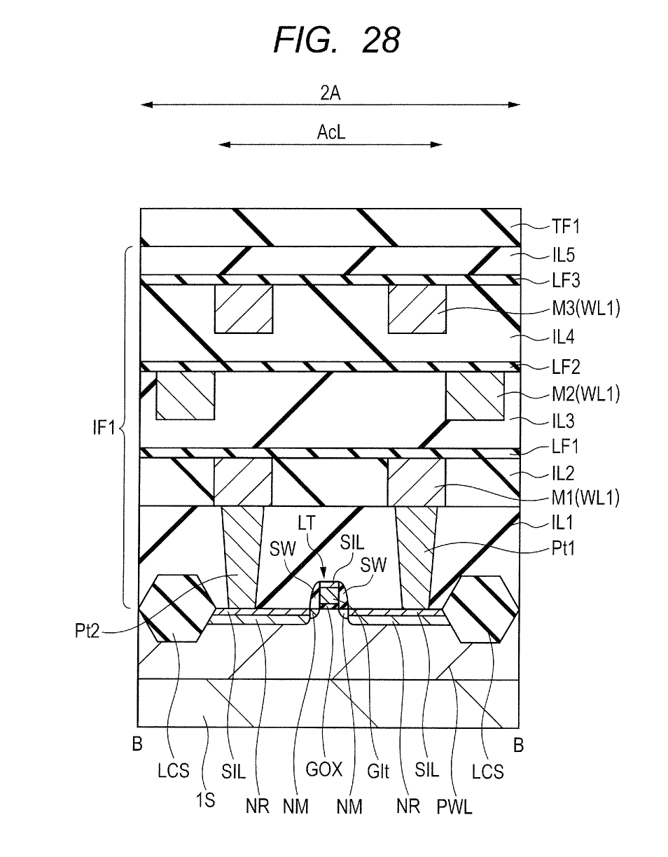

Subsequently, as illustrated in FIGS. 27 and 28, the lamination substrate 11S laminated to the semiconductor substrate 1S is removed in a state where the transmission film TF1 is left over the top surface of the semiconductor substrate 1S, in the pixel region 1A and the peripheral circuit region 2A (Step S25 in FIG. 12).

Specifically, the lamination substrate 11S laminated to the semiconductor substrate 1S can be removed by grinding or polishing the substrate 11S, in the state where the transmission film TF1 is left over the top surface of the semiconductor substrate 1S. Alternatively, the lamination substrate 11S including, for example, single crystalline silicon can be removed by grinding or polishing the substrate 11S to make the thickness thereof thin and then by peeling the thinned lamination substrate 11S with the use of a smart cut method, etc. The smart cut method is one in which the lamination substrate 11S is peeled by introducing hydrogen atoms into the interface between the thinned lamination substrate 11S and the transmission film TF1 with the use of an ion implantation method, and further by cutting the bonding of silicon crystals with the use of a heat treatment.

Thereby, the transmission film TF1 can be formed over the interlayer insulating film IL5 so as to close the concave portion CC1. That is, the transmission film TF1, serving as a transmission film part that transmits the incident light to enter the photodiode PD, is formed over the insulating film part IF1 so as to close the concave portion CC1. And, the space SP1 is formed by the concave portion CC1 and the transmission film TF1. As described above, the concave portion CC1 is formed in the upper surface of the insulating film part IF1 in a portion that overlaps the center CP of the photodiode PD in plan view. Accordingly, the space SP1 is arranged to overlap the center CP of the photodiode PD in plan view.

The space SP1 is a hollow optical waveguide WG1 by which incident light is guided to the photodiode PD. That is, the light that has passed through the transmission film TF1 enters the photodiode PD after passing through the space SP1 as the hollow optical waveguide WG1. Accordingly, the incident light, which has passed through the transmission film TF1 and entered the optical waveguide WG1, can be guided to the photodiode PD without being attenuated.

Subsequently, the plug Pt3, which reaches the wiring M3 formed in the interlayer insulating film IL4, by penetrating the transmission film TF1, the interlayer insulating film IL5, and liner film LF3, is formed in the peripheral circuit region 2A, as illustrated in FIG. 6. Also, the electrode pad EP1 is formed over the transmission film TF1 so as to be electrically coupled to the plug Pt3, in the peripheral circuit region 2A.

Subsequently, as illustrated in FIGS. 5 and 6, the protective film PF1 including, for example, a silicon nitride film is formed over the transmission film TF1 by a CVD method, etc., in the pixel region 1A and the peripheral circuit region 2A (Step S26 in FIG. 12). Also in the peripheral circuit region 2A, the protective film PF1 is formed over the transmission film TF1 so as to cover the electrode pad EP1.

Subsequently, as illustrated in FIG. 5, the opening OP1, which reaches the transmission film TF1 by penetrating the protective film PF1, is formed in the protective film PF1 in a portion located above the concave portion CC1 in plan view, and the color filter layer CF is formed in the opening OP1, in the pixel region 1A (Step S27 in FIG. 12). That is, the color filter layer CF is formed, in plan view, over the transmission film TF1 in a portion located above the concave portion CC1. The color filter layer CF is a film that transmits the light having specific colors such as, for example, red (R), green (G), and blue (B), and does not transmit the light having other colors.

Further, the opening OP2, which reaches the electrode pad EP1 by penetrating the protective film PF1, is formed in the protective film PF1 over the electrode pad EP1, in the peripheral circuit region 2A, as illustrated in FIG. 6. The electrode pad EP1 is exposed at the bottom of the opening OP2.

Subsequently, the micro lens ML whose upper surface is convex is formed over the color filter layer CF (Step S28 in FIG. 12). The micro lens ML is a convex lens whose upper surface is curved and includes a film that transmits light. The micro lens ML can be formed, for example, by forming a transparent film over the color filter layer CF and then by heating and melting the formed film to roll up the upper surface of the film.

The semiconductor device of First Embodiment can be manufactured by the aforementioned steps.

<Semiconductor Device of Variation of First Embodiment and Manufacturing Method Thereof>

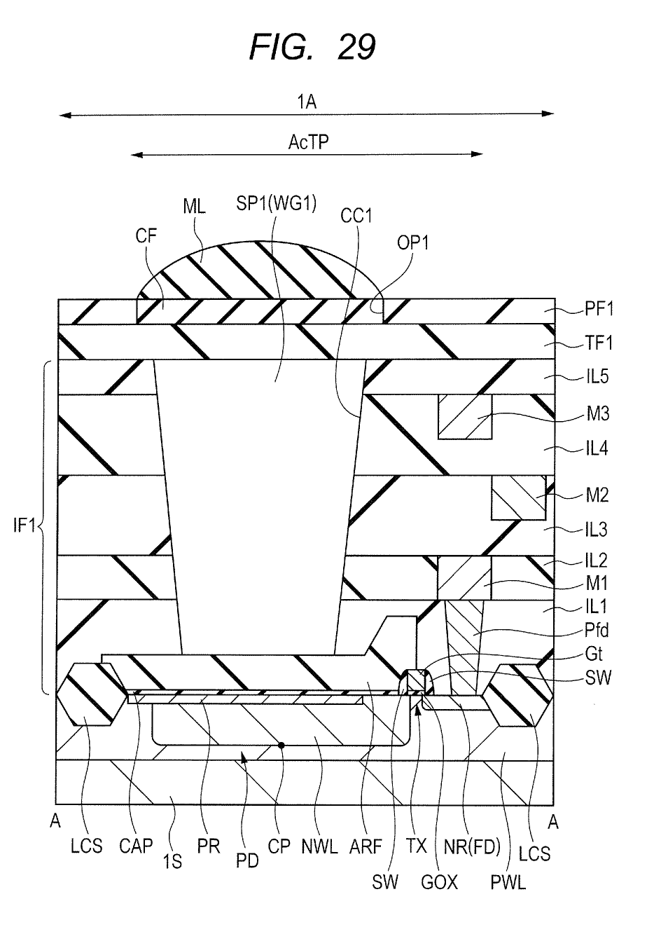

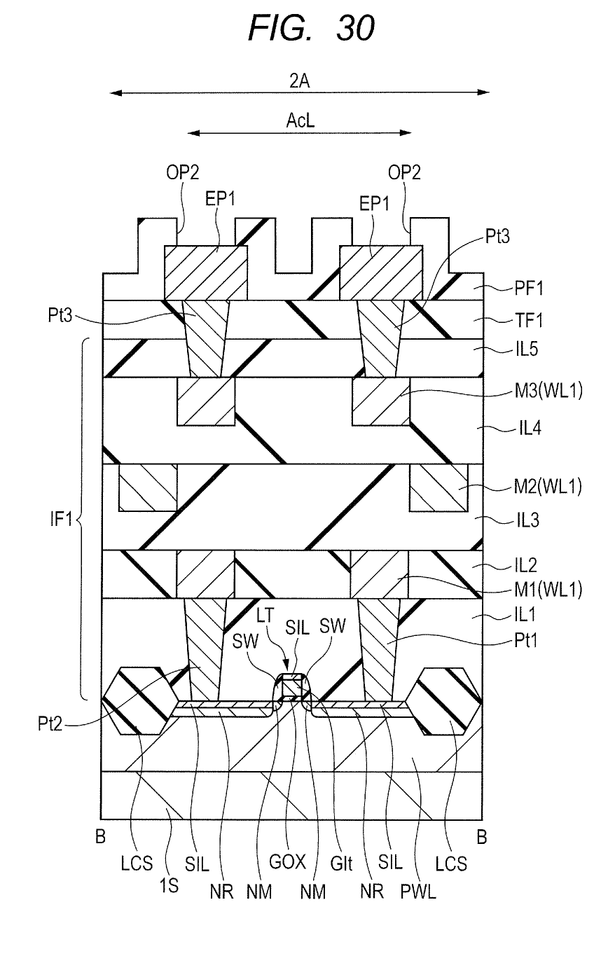

Subsequently, a variation of First Embodiment will be described. FIGS. 29 and 30 are sectional views each illustrating a configuration of a semiconductor device of a variation of First Embodiment. FIG. 29 corresponds to the A-A section in FIG. 2. FIG. 30 corresponds to the B-B section in FIG. 4.

In the semiconductor device of the present variation, the wiring M1 to M3 include Al wiring, instead of Cu wiring. Accordingly, the liner films LF1 to LF3 (see FIGS. 5 and 6), serving as the diffusion preventing films for preventing diffusion of the wiring M1 to M3, may not be provided, as illustrated in FIGS. 29 and 30.

Accordingly, the interlayer insulating film IL2, including, for example, a silicon oxide film or a low dielectric constant film, is formed over the interlayer insulating film IL1, and the wiring M1 including, for example, Al wiring is formed in the interlayer insulating film IL2. The interlayer insulating film IL3, including, for example, a silicon oxide film or a low dielectric constant film, is formed over the interlayer insulating film IL2, and the wiring M2 including, for example, Al wiring is formed in the interlayer insulating film IL3. The interlayer insulating film IL4, including, for example, a silicon oxide film or a low dielectric constant film, is formed over the interlayer insulating film IL3, and the wiring M3 including, for example, Al wiring is formed in the interlayer insulating film IL4. The interlayer insulating film IL5, including, for example, a silicon oxide film or a low dielectric constant film, is formed over the interlayer insulating film IL4.

Thus, a wiring layer WL1 (see FIG. 30) is formed by the wiring M1 to M3 respectively formed in each of the interlayer insulating films IL2 to IL4, of the interlayer insulating films IL2 to IL5. When the interlayer insulating films IL1 to IL5, the antireflection film ARF, and the cap insulating film CAP are collectively referred to as an insulating film part IF1, the insulating film part IF1 is formed over a main surface of the semiconductor substrate 1S, i.e., over the top surface thereof so as to cover the photodiode PD. A concave portion CC1, which reaches the antireflection film ARF by penetrating the interlayer insulating films IL1 to IL5, is also formed in the pixel region 1A. When the interlayer insulating films IL1 to IL5, the antireflection film ARF, and the cap insulating film CAP are collectively referred to as the insulating film part IF1, the concave portion CC1 is therefore formed in the upper surface of the insulating film part IF1 in a portion that overlaps the center CP of the photodiode PD in plan view.

Of the semiconductor device of the present variation, other parts, including those located below the interlayer insulating film IL2, the transmission film TF1, and those located above the transmission film TF1, are the same as those of the semiconductor device of First Embodiment.

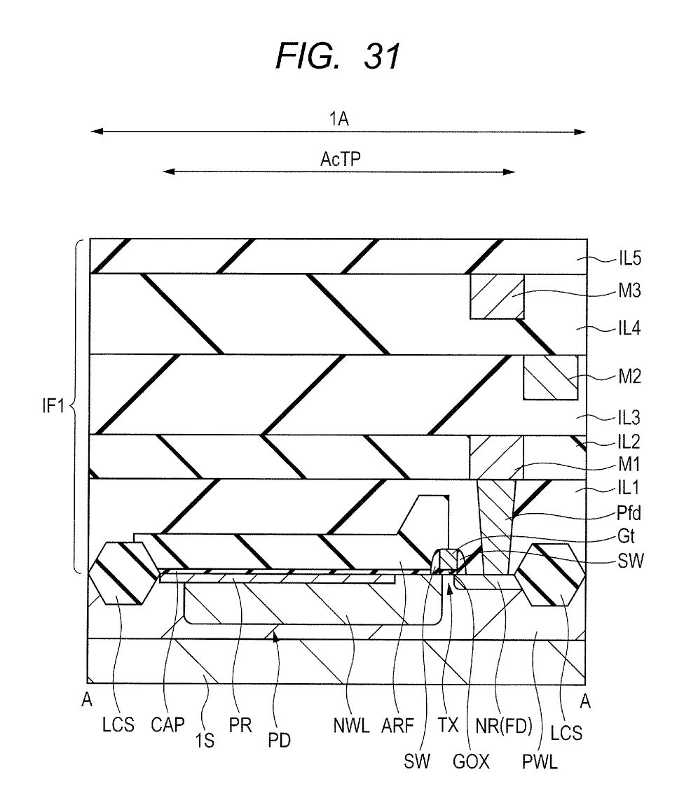

FIGS. 31 to 38 are sectional views each illustrating a manufacturing step of the semiconductor device of the variation of First Embodiment. Each of the sectional views of FIGS. 31 to 38 corresponds to the A-A section in FIG. 29 or the B-B section in FIG. 30.

In the present variation, after the steps of Step S11 to Step S20 in FIG. 11 are performed to form the interlayer insulating film IL1, the wiring layer WL1, including the interlayer insulating films IL2 to IL5 and the wiring M1 to M3, is formed over the interlayer insulating film IL1 (Step S21 in FIG. 12), similarly to First Embodiment.

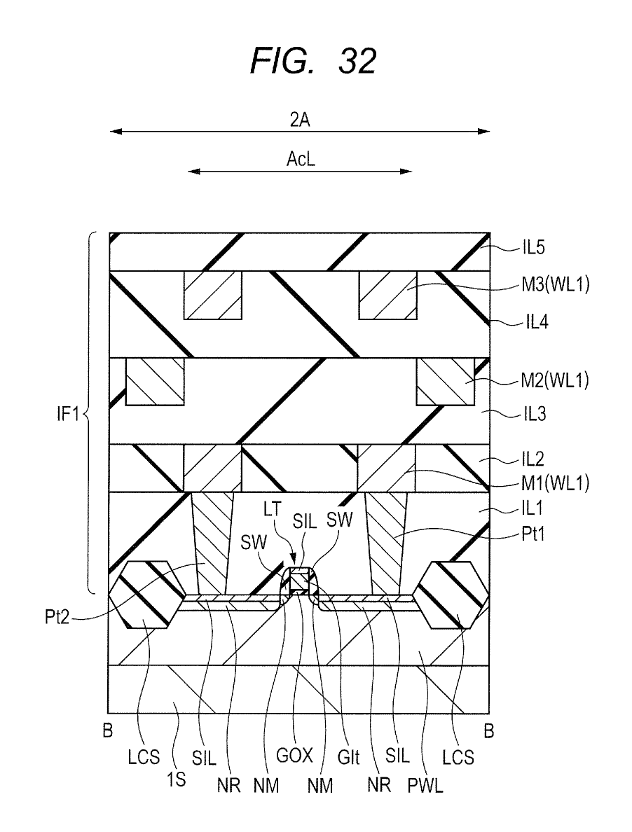

However, the liner films LF1 to LF3 are not formed in the present variation, unlike First Embodiment. Accordingly, the interlayer insulating film IL2, including, for example, a silicon oxide film or a low dielectric constant film, is formed over the interlayer insulating film IL1, and the wiring M1 including, for example, Al wiring is formed in the interlayer insulating film IL2, as illustrated in FIGS. 31 and 32. The interlayer insulating film IL3, including, for example, a silicon oxide film or a low dielectric constant film, is formed over the interlayer insulating film IL2, and the wiring M2 including, for example, Al wiring is formed in the interlayer insulating film IL3. The interlayer insulating film IL4, including, for example, a silicon oxide film or a low dielectric constant film, is formed over the interlayer insulating film IL3, and the wiring M3 including, for example, Al wiring is formed in the interlayer insulating film IL4. The interlayer insulating film IL5, including, for example, a silicon oxide film or a low dielectric constant film, is formed over the interlayer insulating film IL4.

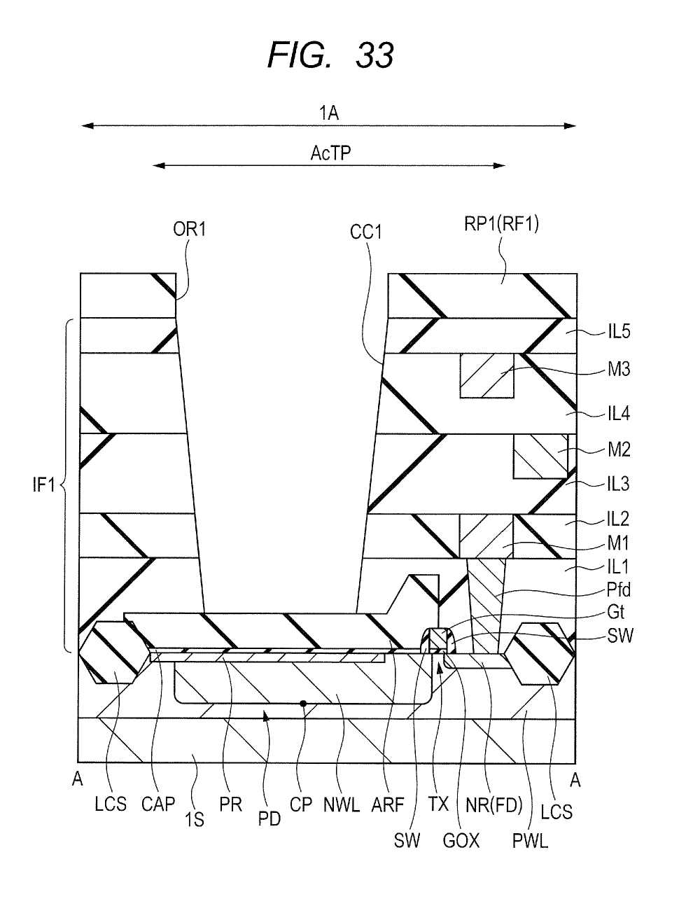

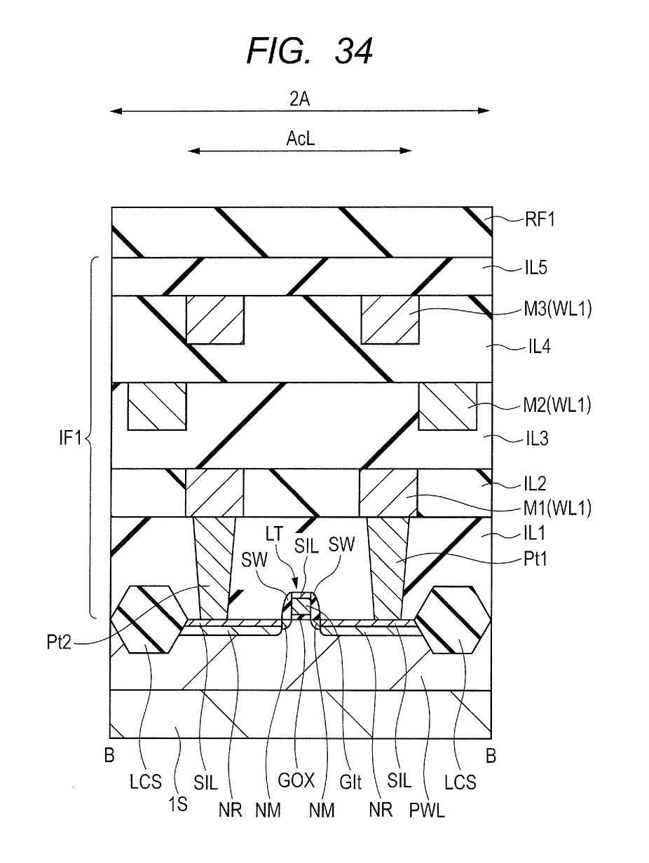

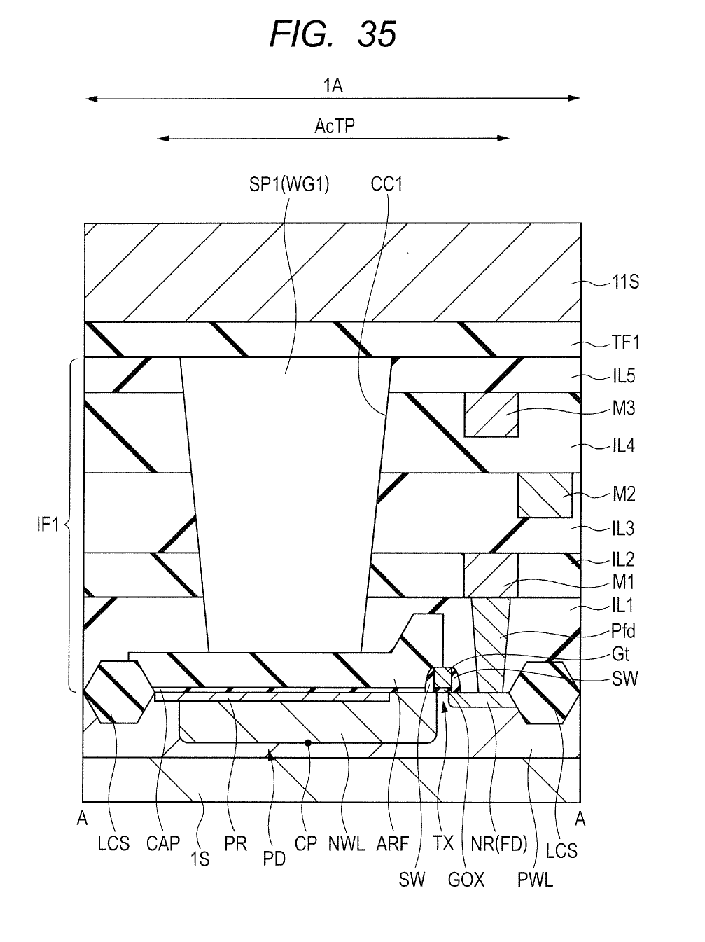

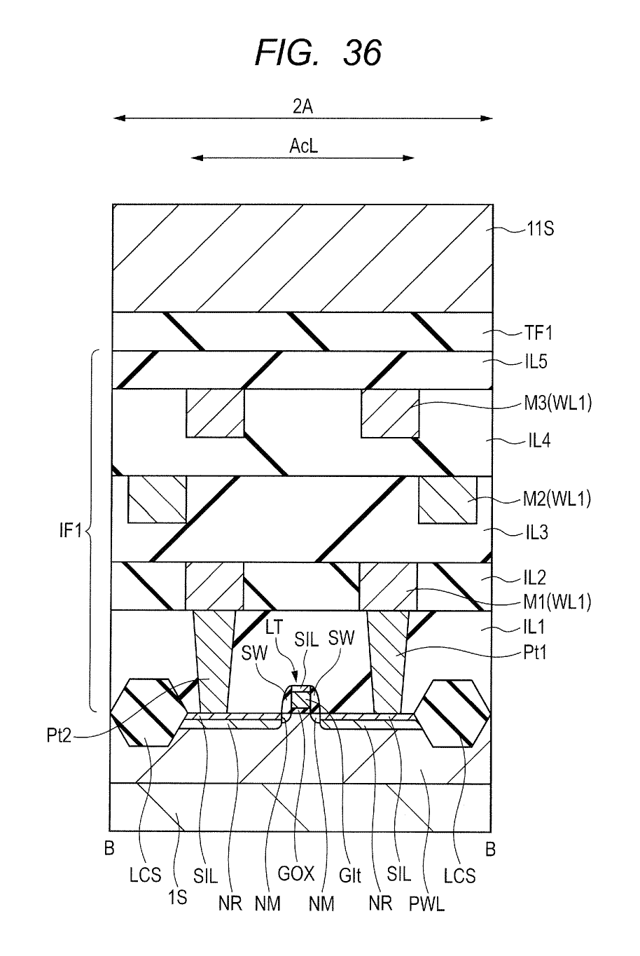

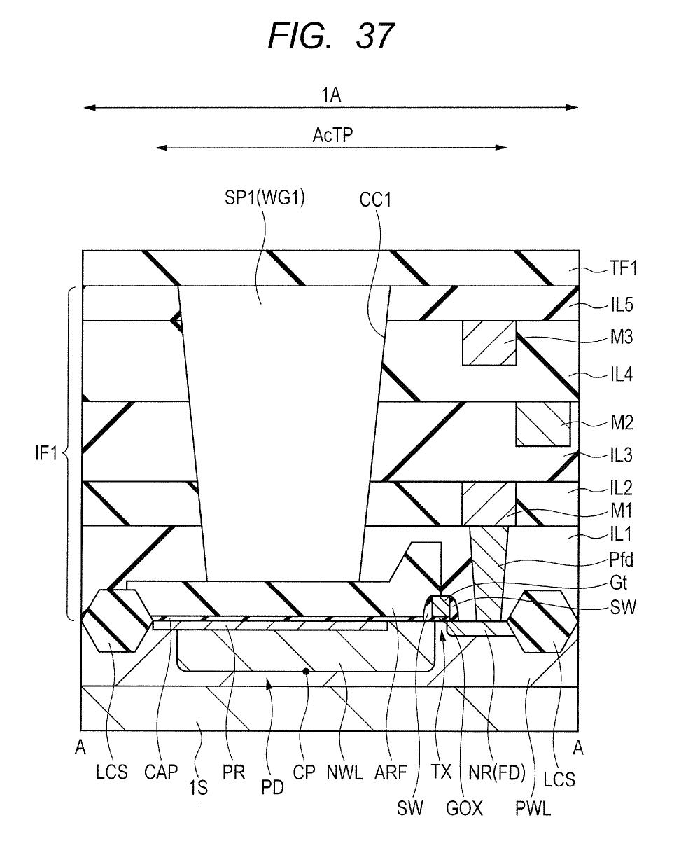

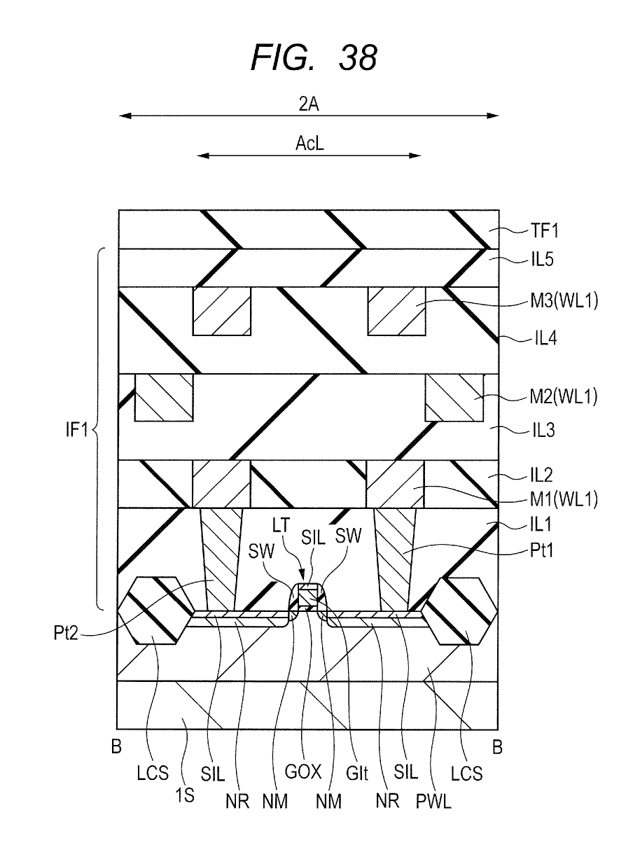

Subsequently, the concave portion CC1 is formed by performing Step S22 in FIG. 12, as illustrated in FIGS. 33 and 34, similarly to First Embodiment. Subsequently, the transmission film TF1 is formed over the top surface of the lamination substrate 11S by performing Step S23 in FIG. 12, as illustrated in FIGS. 35 and 36, similarly to First Embodiment. Subsequently, the lamination substrate 11S is laminated by performing Step S24 in FIG. 12, as illustrated FIGS. 35 and 36, similarly to First Embodiment. Subsequently, the lamination substrate 11S is removed by performing Step S25 in FIG. 12, as illustrated in FIGS. 37 and 38, similarly to First Embodiment. Subsequently, the semiconductor device of the present variation can be manufactured by performing the steps of Step S26 to Step S28 in FIG. 12, as illustrated in FIGS. 29 and 30.

<Attenuation of Incident Light to Enter Photodiode>

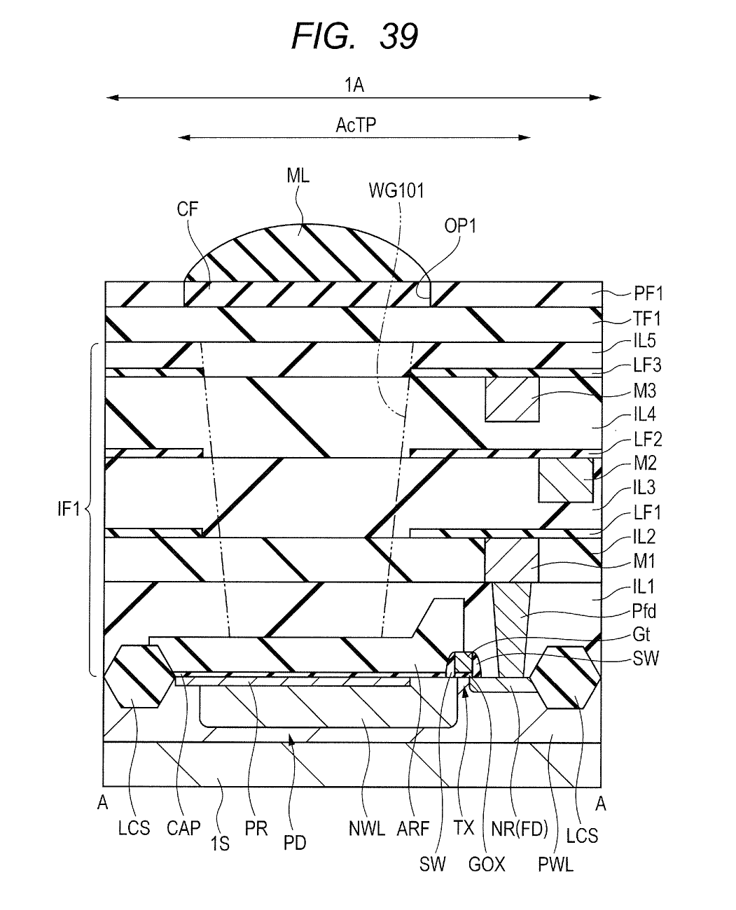

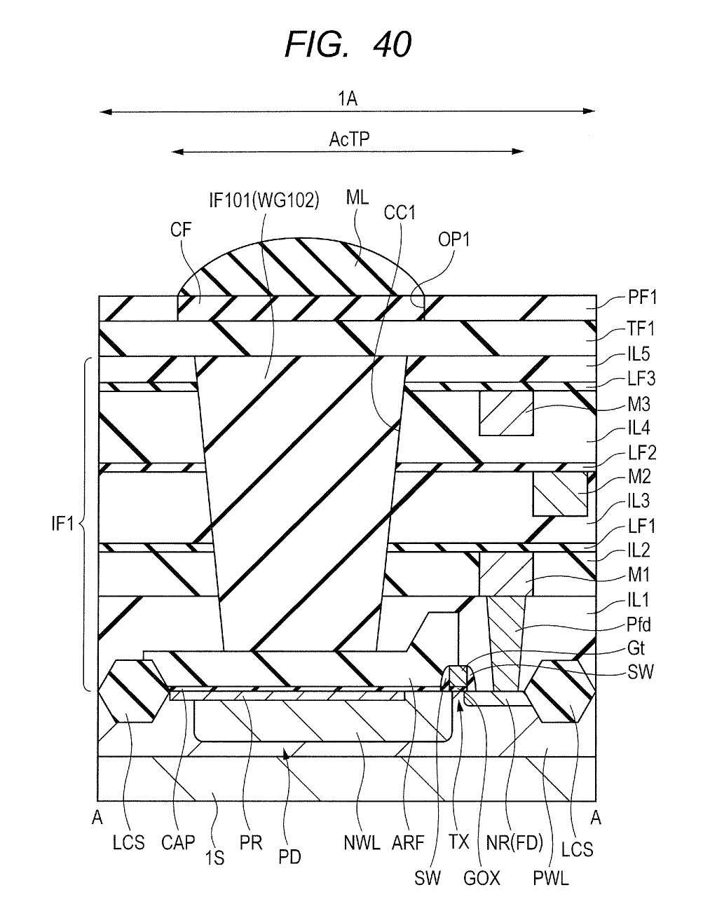

Subsequently, attenuation of the incident light to enter the photodiode PD after passing through an optical waveguide will be described in comparison with the case of a semiconductor device of First Comparative Example and Second Comparative Example. FIG. 39 is a sectional view illustrating a configuration of the semiconductor device of First Comparative Example. FIG. 40 is a sectional view illustrating a configuration of the semiconductor device of Second Comparative Example.

In the semiconductor device of First Comparative Example, the concave portion CC1 (see FIG. 5) is not formed in the insulating film part IF1 in a portion located above the photodiode PD, as illustrated in FIG. 39. Accordingly, the light, which has passed through the micro lens ML and the color filter layer CF, enters the photodiode PD after passing through an optical waveguide WG101 formed in the interlayer insulating films IL1 to IL5.

However, there is no difference between the refractive index inside the optical waveguide WG101 and that outside the optical waveguide WG101, in the semiconductor device of First Comparative Example. Accordingly, the light passing through the optical waveguide WG101 cannot be confined inside the optical waveguide WG101, and of the light that has passed through the color filter layer CF, a ratio of the light that reaches the photodiode PD cannot be increased. Accordingly, the light amount of the incident light to enter the photodiode PD is decreased, and hence the sensitivity of the CMOS image sensor cannot be improved.

In the semiconductor device of Second Comparative Example, the concave portion CC1 is formed in the insulating film part IF1 in a portion located above the photodiode PD, but the space SP1 (see FIG. 5) is not formed because the inside of the concave portion CC1 is filled with an insulating film IF101 including, for example, a silicon nitride film, etc., as illustrated in FIG. 40. Also, an optical waveguide WG102 is formed by the insulating film IF101.

In the semiconductor device of Second Comparative Example, it can be considered that the insulating film IF101 is caused to include a silicon nitride film having a refractive index larger than those of the interlayer insulating films IL1 to IL5 each including, for example, a silicon oxide film. That is, it can be considered that the refractive index inside the optical waveguide WG102 is made larger than that outside the optical waveguide WG102. Thereby, the light passing through the optical waveguide WG102 is reflected by the side surface of the concave portion CC1, thereby allowing the light to be confined inside the optical waveguide WG102.

However, in the manufacturing steps of the semiconductor device of Second Comparative Example, it is difficult to fill the inside of the concave portion CC1 with the insulating film IF101 after the concave portion CC1 is formed. It is also difficult to flatten the insulating film IF101 over the interlayer insulating film IL5, i.e., outside the concave portion CC1 by grinding or polishing the film IF101 after the concave portion CC1 is filled with the insulating film IF101. Accordingly, there is the fear that: the number of steps in the manufacturing steps of a semiconductor device or the period of time necessary for each step may be increased; and hence manufacturing cost may be increased.

Further, the incident light to enter the photodiode PD is attenuated while passing through the optical waveguide WG102 including the insulating film IF101 embedded in the concave portion CC1, and hence the light amount of the incident light to enter the photodiode PD is decreased, which leads to a decrease in the sensitivity of the CMOS image sensor and a decrease in the performance of the semiconductor device.

In a semiconductor device including a high-sensitive CMOS image sensor such as, for example, a CMOS image sensor for a single-lens reflex camera, the length of one side of a pixel exceeds 1 μm having a rectangular shape is, for example, approximately 2 to 4 μm in plan view, as describe above with reference to FIGS. 7 and 8. In such a large pixel having one side whose length is larger than 1 μm, when the concave portion CC1, having a width larger than, for example, 1 μm, is formed and the inside thereof is filled, it is necessary to form the insulating film IF101 having a thickness almost the same as the depth of the concave portion CC1. Because the depth DP of the concave portion CC1 may be 3 to 5 μm, as described above with reference to FIG. 5, it is necessary to remove the insulating film IF101, having a thickness of approximately 3 to 5 μm and located over the interlayer insulating film IL5, by grinding or polishing the film IF101, after the insulating film IF101 is formed. Accordingly, when the length of one side of a pixel exceeds there is the fear that: the number of steps in the manufacturing steps of a semiconductor device or the period of time necessary for each step may be further increased; and hence manufacturing cost may be further increased. Additionally, when the insulating film IF101 including a silicon nitride film is deposited to be thick, the semiconductor substrate 1S may be warped because the silicon nitride film has high stress, which also creates the problem that the semiconductor substrate 1S may break.

In First Comparative Example illustrated in FIG. 39, the case where the wiring M1 to M3 include Cu wiring is illustrated, and the case where the insulating film part IF1 includes the liner films LF1 to LF3 in addition to the interlayer insulating films IL1 to IL5 is illustrated, as described above, similarly to First Embodiment. In such a case, if the liner films LF1 to LF3 in a portion located above the photodiode PD are left, incident light is reflected by an interface between any one of the liner films LF1 to LF3, each including a material different from that of each of the interlayer insulating films IL2 to IL5, and any one of the interlayer insulating films IL2 to IL5, thereby causing the incident light to be attenuated.

Accordingly, when the concave portion CC1 is not formed in the upper surface of the insulating film part IF1 in a portion located above the photodiode PD and the insulating film part IF1 is left to use as an optical waveguide, the interlayer insulating films IL1 to IL5 can be left, but it is necessary to remove the liner films LF1 to LF3 in a portion located above the photodiode PD. Accordingly, the step of removing each of the liner films LF1 to LF3 in a portion located above the photodiode PD by etching is performed when each of the liner films LF1 to LF3 is formed, which creates the fear that the number of steps in the manufacturing steps of the semiconductor device may be increased.

In the technique described in the aforementioned Patent Document 1, an optical waveguide, having both a core formed in a light transmission layer by silicon nitride and an air gap formed, in plan view, annularly along the whole outer periphery of the core, is provided. However, in the technique described in the aforementioned Patent Document 1, the air gap is provided as a portion having a refractive index smaller than that of the core in order to reduce an amount of the light that leaks from the core including silicon nitride, and by using the air gap as a clad layer, the optical waveguide having both the core and the clad layer is formed. Accordingly, the light to enter the optical waveguide is confined in the core, but the light is further attenuated in comparison with the case where the light passes through a hollow optical waveguide.

<Main Characteristics and Effects of Present Embodiment>

In the semiconductor device of First Embodiment, the insulating film part IF1 is formed over a main surface of the semiconductor substrate 1S so as to cover the photodiode PD, the concave portion CC1 is formed in the upper surface of the insulating film part IF1 in a portion that overlaps the center CP of the photodiode PD, and the transmission film TF1 is formed over the insulating film part IF1 so as to close the concave portion CC1. The space SP1 is formed by the concave portion CC1 and the transmission film TF1, and the space SP1 is arranged to overlap the center CP of the photodiode PD in plan view.

Thereby, incident light enters at least the central portion of the photodiode PD in plan view, after passing through the space SP1 serving as the hollow optical waveguide WG1. Accordingly, the incident light is not attenuated while passing through the optical waveguide, and hence both the sensitivity of the CMOS image sensor and the performance of the semiconductor device can be improved.

Also, it is unnecessary to fill the inside of the concave portion CC1 with an insulating film after the concave portion CC1 is formed, and it is unnecessary to flatten the insulating film over the interlayer insulating film IL5, i.e., outside the concave portion CC1 by grinding or polishing the insulating film after the concave portion CC1 is filled with the insulating film. Accordingly, the number of steps in the manufacturing steps of the semiconductor device or the period of time necessary for each step can be reduced; and hence manufacturing cost can be reduced. When the length of one side of the pixel exceeds 1 μm, the effect, in which the number of steps in the manufacturing steps of the semiconductor device or the period of time necessary for each step is reduced, is further increased; and the effect, in which manufacturing cost is reduced, is further increased.

Variations in the position of the space in plan view and in the height position thereof can be further reduced in comparison with the case where the concave portion CC1 is formed and then the inside of the concave portion CC1 is filled with an insulating film such that a space is left.

Further, even when the wiring M1 to M3 include Cu wiring and the insulating film part IF1 includes the liner films LF1 to LF3, the liner films LF1 to LF3 in a portion located above the photodiode PD can be collectively removed in the step of forming the concave portion CC1. Thereby, the number of steps in the manufacturing steps of the semiconductor device can be reduced. Further, incident light is not reflected by an interface between any one of the liner films LF1 to LF3, each including a material different from that of each of the interlayer insulating films IL2 to IL5, and any one of the interlayer insulating films IL2 to IL5. Accordingly, both the sensitivity of the CMOS image sensor and the performance of the semiconductor device can be improved.

### Second Embodiment

In Second Embodiment, an example will be described, in which a sidewall insulating film is further formed in the side surface of the concave portion in the semiconductor device of First Embodiment.

A configuration of a semiconductor device of Second

Embodiment and an element structure in a peripheral circuit region are the same as those of the semiconductor device of First Embodiment, which have been described with reference to FIGS. 1 to 4 and 6, and hence description thereof will be omitted.

<Element Structure in Pixel Region>

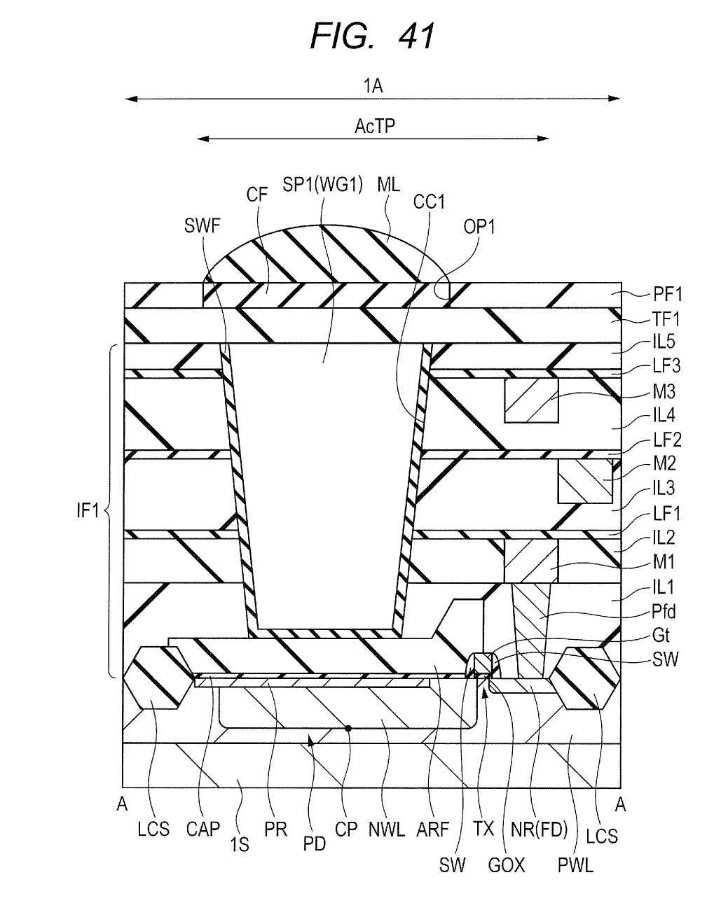

Subsequently, an element structure in a pixel region will be described. FIG. 41 is a sectional view illustrating a configuration of the semiconductor device of Second Embodiment. FIG. 41 corresponds to the A-A section in FIG. 2.

The element structure in the pixel region in Second Embodiment is the same as that in the pixel region in First Embodiment described with reference to FIG. 5, except that a sidewall insulating film SWF is formed in the side surface of the concave portion CC1.

On the other hand, the sidewall insulating film SWF is formed in the side surface of the concave portion CC1 in Second Embodiment, as illustrated in FIG. 41. The sidewall insulating film SWF includes, for example, a silicon oxide film, a silicon nitride film, or a laminated film formed by a silicon oxide film and a silicon nitride film. Thereby, light can be reflected by the top surface of the sidewall insulating film SWF or by the interface between the sidewall insulating film SWF and the side surface of the concave portion CC1 when the light, passing through the hollow optical waveguide WG1, enters the side surface of the concave portion CC1, and hence the light amount of the light, which reaches the photodiode PD after passing through the hollow optical waveguide WG1, can be increased. Alternatively, when the sidewall insulating film SWF includes a laminated film, light can be reflected even by the interface between the layers, and hence the light amount of the light to reach the photodiode PD can be increased. Accordingly, both the sensitivity of the CMOS image sensor and the performance of the semiconductor device can be improved.

Herein, the sidewall insulating film SWF may be formed also in the bottom surface of the concave portion CC1.

<Manufacturing Method of Semiconductor Device>

Subsequently, a manufacturing method of the semiconductor device of Second Embodiment will be described.

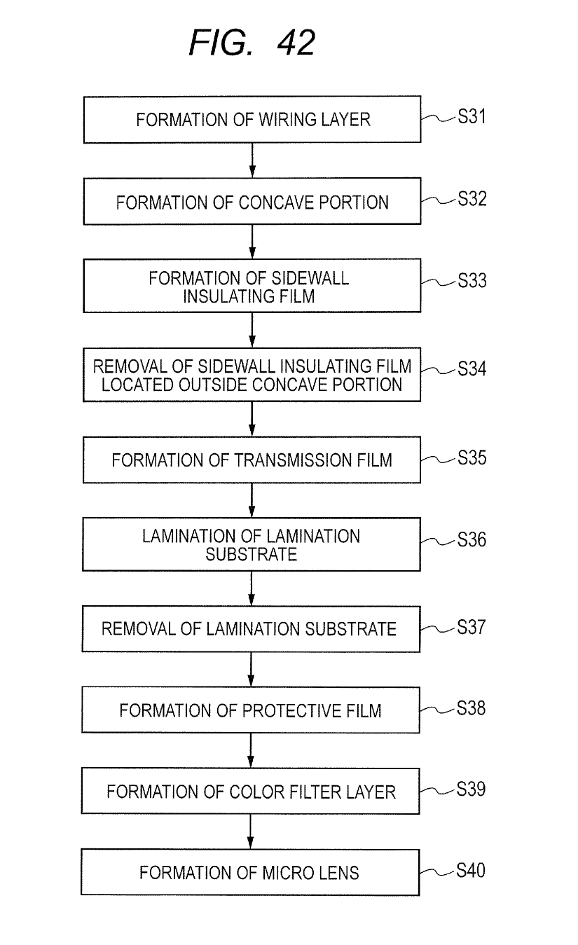

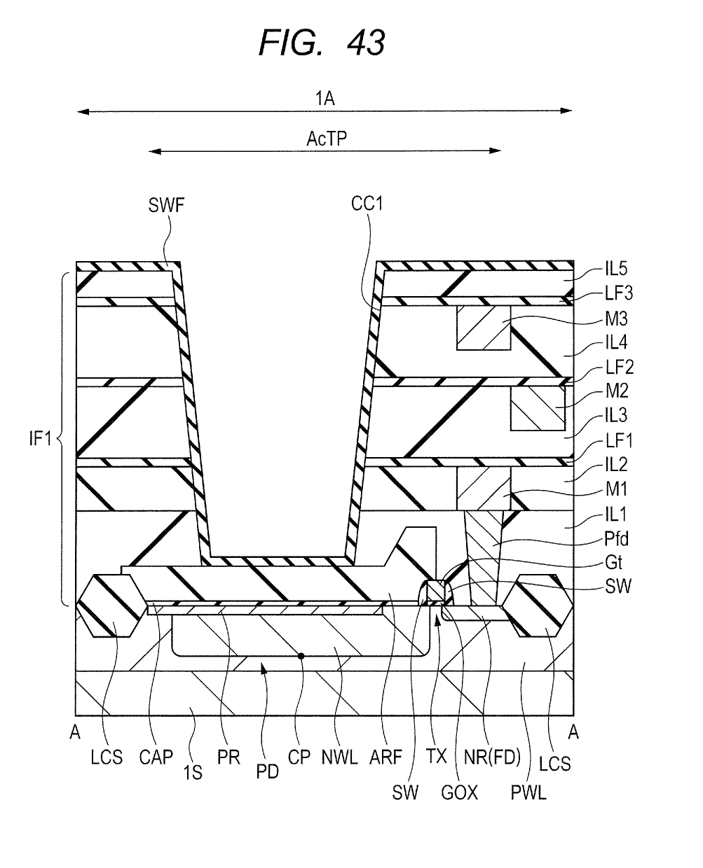

FIG. 42 is a manufacturing process flow chart illustrating part of manufacturing steps of the semiconductor device of Second Embodiment. FIGS. 43 to 45 are sectional views each illustrating a manufacturing step of the semiconductor device of second Embodiment. FIG. 42 illustrates, of the manufacturing steps of the semiconductor device of Second Embodiment, mainly the manufacturing steps in the pixel region 1A. Each of the sectional views of FIGS. 43 to 45 corresponds to the A-A section in FIG. 2 or the B-B section in FIG. 4.

In the Second Embodiment, after the steps of Step S11 to Step S20 in FIG. 11 are performed to form the interlayer insulating film IL1, the wiring layer WL1 is formed over the interlayer insulating film IL1 by performing the same step as Step S21 in FIG. 12 (Step S31 in FIG. 42), similarly to First Embodiment. Subsequently, the concave portion CC1 is formed by performing the same step as Step S22 in FIG. 12 (Step S32 in FIG. 42).

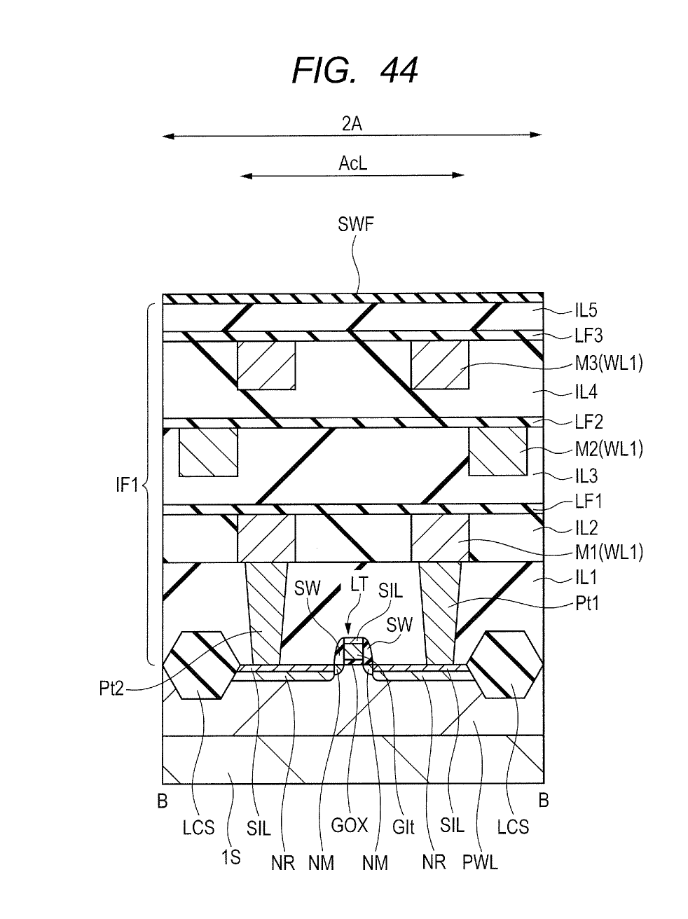

Subsequently, as illustrated in FIGS. 43 and 44, the sidewall insulating film SWF is formed over the side surface of the concave portion CC1 and over the interlayer insulating film IL5 in the pixel region 1A and the peripheral circuit region 2A (Step S33 in FIG. 42). In Step S33, the sidewall insulating film SWF, including, for example, a silicon oxide film, a silicon nitride film, or a laminated film formed by a silicon oxide film and a silicon nitride film, is formed over the side surface of the concave portion CC1 and over the interlayer insulating film IL5 by a CVD method, etc.

Herein, the sidewall insulating film SWF may be formed also in the bottom surface of the concave portion CC1.

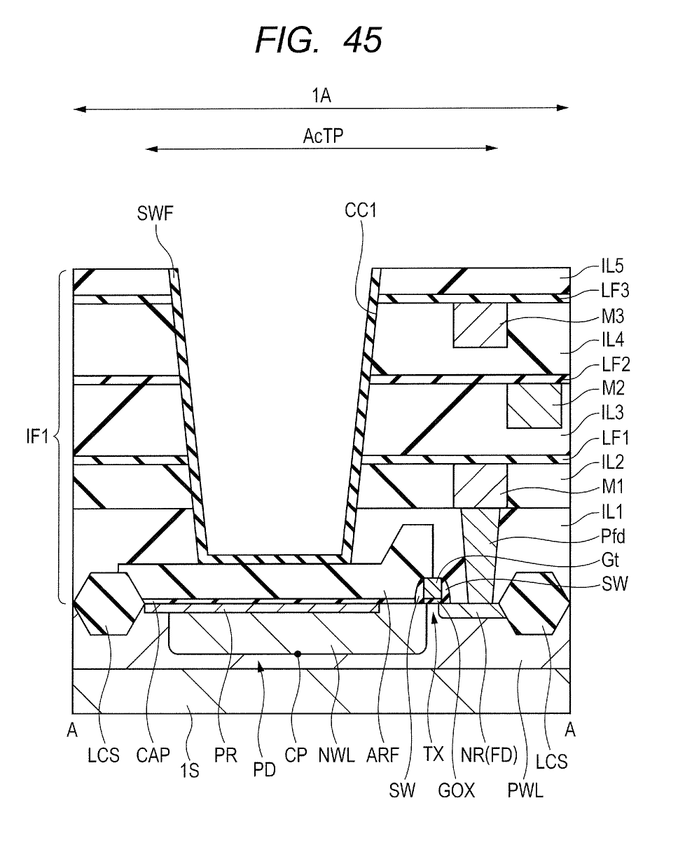

Subsequently, the sidewall insulating film SWF outside the concave portion CC1 is removed in the pixel region 1A and the peripheral circuit region 2A (Step S34 in FIG. 42). In Step S34, the sidewall insulating film SWF outside the concave portion CC1 and in the bottom surface of the concave portion CC1 is removed, for example, by etching back the sidewall insulating film SWF, etc., in the pixel region 1A, as illustrated in FIG. 45. The sectional structure in the peripheral circuit region 2A, obtained after Step S34 is performed, is the same as that illustrated in FIG. 22.

Herein, the sidewall insulating film SWF may be left in the bottom surface of the concave portion CC1 by covering part of the concave portion CC1 with a resist film and by etching back the sidewall insulating film SWF.

Subsequently, the transmission film TF1 is formed over the top surface of the lamination substrate 11S by performing the same step as Step S23 in FIG. 23 (Step S35 in FIG. 42), similarly to First Embodiment. Subsequently, the lamination substrate 11S is laminated by performing the same step as Step S24 in FIG. 12 (Step S36 in FIG. 42), similarly to First Embodiment. Subsequently, the lamination substrate 11S is removed by performing the same step as Step S25 in FIG. 12 (Step S37 in FIG. 42), similarly to First Embodiment. Subsequently, by performing the same steps as those of Step S26 to Step S28 in FIG. 12 (Step S38 to Step S40 in FIG. 42), the semiconductor device of Second Embodiment can be manufactured, as illustrated in FIG. 41 and FIG. 6.

<Main Characteristics and Effects of Present Embodiment>

The semiconductor device of Second Embodiment has the same characteristics as those of the semiconductor device of First Embodiment, such as, for example, the fact that the space SP1 is arranged to overlap the center CP of the photodiode PD in plan view, and hence the semiconductor device of Second Embodiment has the same effects as those of the semiconductor device of First Embodiment.

In addition to that, the sidewall insulating film SWF is formed in the side surface of the concave portion CC1 in the semiconductor device of Second Embodiment. Thereby, light can be reflected by the top surface of the sidewall insulating film SWF or by the interface between the sidewall insulating film SWF and the side surface of the concave portion CC1 when the light, passing through the hollow optical waveguide WG1, enters the side surface of the concave portion CC1, and hence the light amount of the light, which reaches the photodiode PD after passing through the hollow optical waveguide WG1, can be increased. Alternatively, when the sidewall insulating film SWF includes a laminated film, the light can be reflected even by the interface between the layers, and hence the light amount of the light to reach the photodiode PD can be increased. Accordingly, the sensitivity of the CMOS image sensor and the performance of the semiconductor device can be further improved in comparison with First Embodiment.

### Third Embodiment

In First Embodiment, an example has been described, in which the concave portion is closed: by laminating the lamination substrate, over which the transmission film for closing the concave portion is formed, so that the transmission film is joined; and then by removing the lamination substrate in a state where the transmission film is left. On the other hand, an example will be described in Third Embodiment, in which the concave portion is closed by adhering a supporting substrate in which the micro lens and the color filter layer are formed.

A configuration of a semiconductor device of Third Embodiment is the same as that of the semiconductor device of First Embodiment described with reference to FIGS. 1 to 4, and hence description thereof will be omitted.

<Element Structure in Pixel Region and Peripheral Circuit>

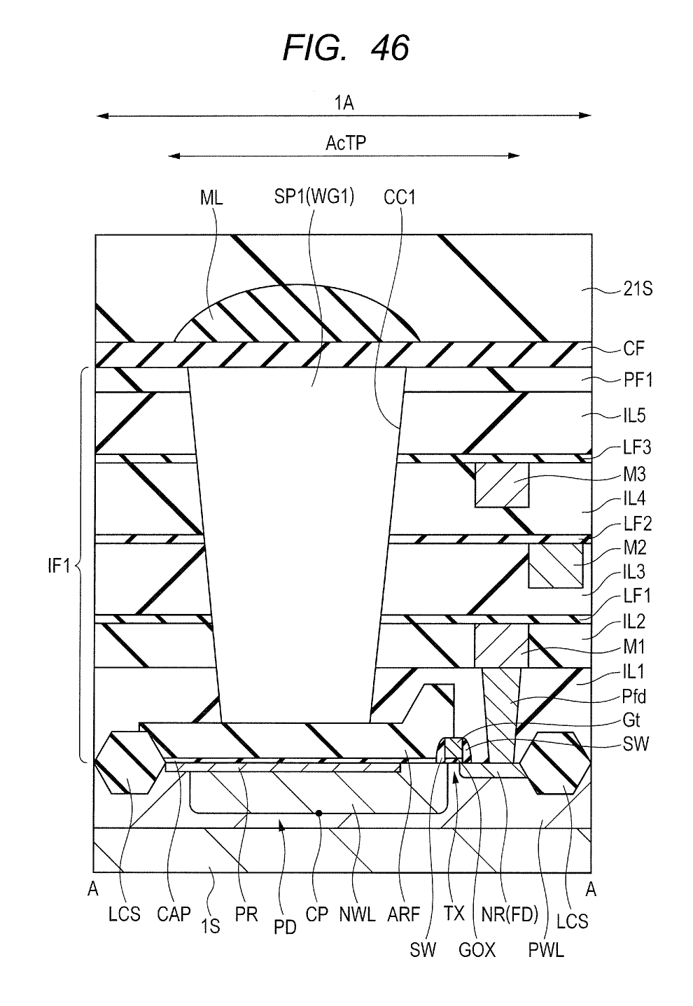

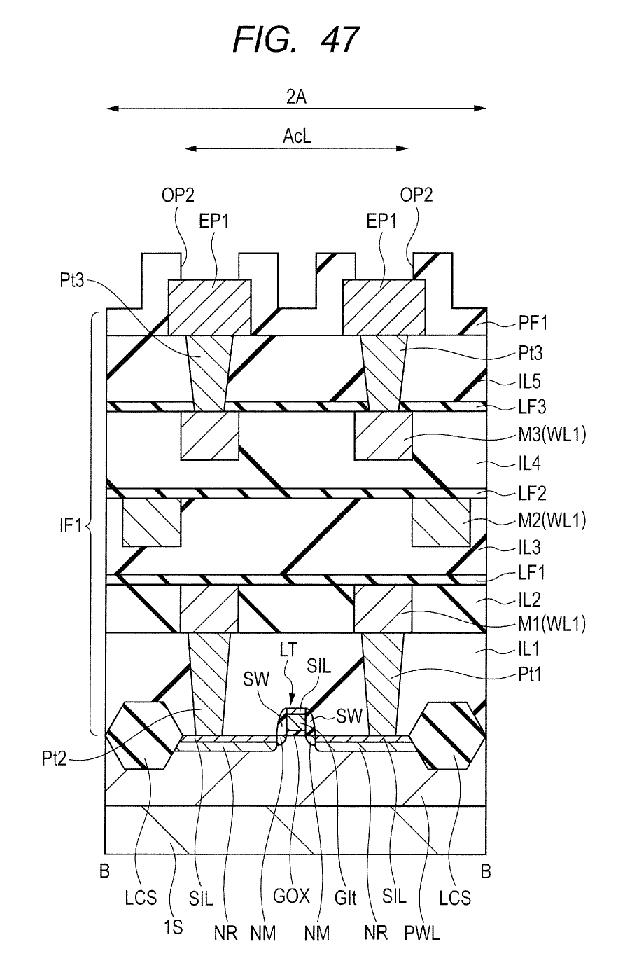

Subsequently, the element structure in each of a pixel region and a peripheral circuit region will be described. FIGS. 46 and 47 are sectional views each illustrating the configuration of the semiconductor device of Third Embodiment. FIG. 46 corresponds to the A-A section in FIG. 2. FIG. 47 corresponds to the B-B section in FIG. 4.

The element structure in each of the pixel region and the peripheral circuit in Third Embodiment is the same as that in each of the pixel region and the peripheral circuit region in the semiconductor device of First Embodiment described with reference to FIGS. 5 and 6, except a portion located above the interlayer insulating film IL5.

On the other hand, the protective film PF1 is formed directly over the interlayer insulating film IL5 without forming the transmission film TF1 (see FIGS. 5 and 6) in the pixel region 1A and the peripheral circuit region 2A in Third Embodiment, as illustrated in FIG. 46.

Herein, when the interlayer insulating films IL1 to IL5, the liner films LF1 to LF3, the antireflection film ARF, and the cap insulating film CAP are collectively referred to as an insulating film part IF1, the insulating film part IF1 is formed over a main surface of the semiconductor substrate 1S, i.e., over the top surface thereof so as to cover the photodiode PD. In the pixel region 1A, the concave portion CC1 is formed in the upper surface of the insulating film part IF1 in a portion that overlaps the center CP of the photodiode PD in plan view.

In the peripheral circuit region 2A, a plug Pt3, which reaches the wiring M3 by penetrating the interlayer insulating film IL5 and the liner film LF3, is formed. Also in the peripheral circuit region 2A, the electrode pad EP1 is formed over the interlayer insulating film IL5, and the electrode pad EP1 is electrically coupled to the plug Pt3.

In the pixel region 1A, the color filter layer CF is formed over the protective film PF1. The color filter layer CF transmits, of the incident light to enter the photodiode PD, the light having specific colors. The color filter layer CF is a transmission film part formed over the protective film PF1, i.e., over the insulating film part IF1 so as to close the concave portion CC1. The hollow space SP1 is formed by the concave portion CC1 and the color filter layer CF. As described above, the concave portion CC1 is formed in the upper surface of the insulating film part IF1 in a portion that overlaps the center CP of the photodiode PD in plan view. Accordingly, the space SP1 is arranged to overlap the center CP of the photodiode PD in plan view.

In the peripheral circuit region 2A, the protective film PF1 is formed over the interlayer insulating film IL5 so as to cover the electrode pad EP1. An opening OP2, which reaches the electrode pad EP1 by penetrating the protective film PF1, is formed in the protective film PF1 over the electrode pad EP1, and the electrode pad EP1 is exposed at the bottom of the opening OP2.

In the pixel region 1A, the micro lens ML whose upper surface is convex is formed over the color filter layer CF in a portion located above the concave portion CC1. Also, a transparent supporting substrate 21S is formed over the color filter layer CF so as to cover the micro lens ML.

<Manufacturing Method of Semiconductor Device>

Subsequently, a manufacturing method of the semiconductor device of Third Embodiment will be described.

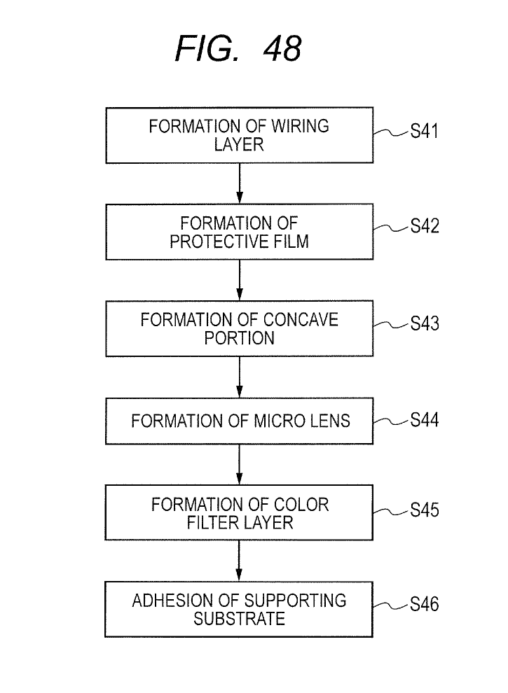

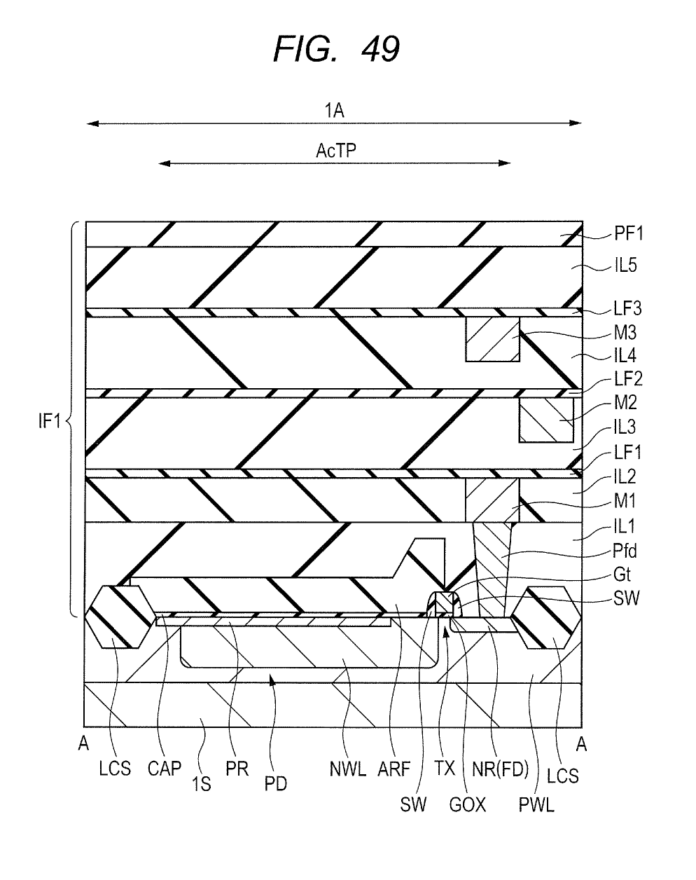

FIG. 48 is a manufacturing process flow chart illustrating part of manufacturing steps of the semiconductor device of Third Embodiment. FIGS. 49 to 51 are sectional views each illustrating a manufacturing step of the semiconductor device of Third Embodiment. FIG. 48 illustrates, of the manufacturing steps of the semiconductor device of third Embodiment, mainly the manufacturing steps in the pixel region 1A. Each of the sectional views of FIGS. 49 to 51 corresponds to the A-A section in FIG. 46 or the B-B section in FIG. 47.

In Third Embodiment, after the steps of Step S11 to Step S20 in FIG. 11 are performed to form the interlayer insulating film IL1, the wiring layer WL1 (see FIG. 22) is formed over the interlayer insulating film IL1 by performing the same step as Step S21 in FIG. 12 (Step S41 in FIG. 48), similarly to First Embodiment.

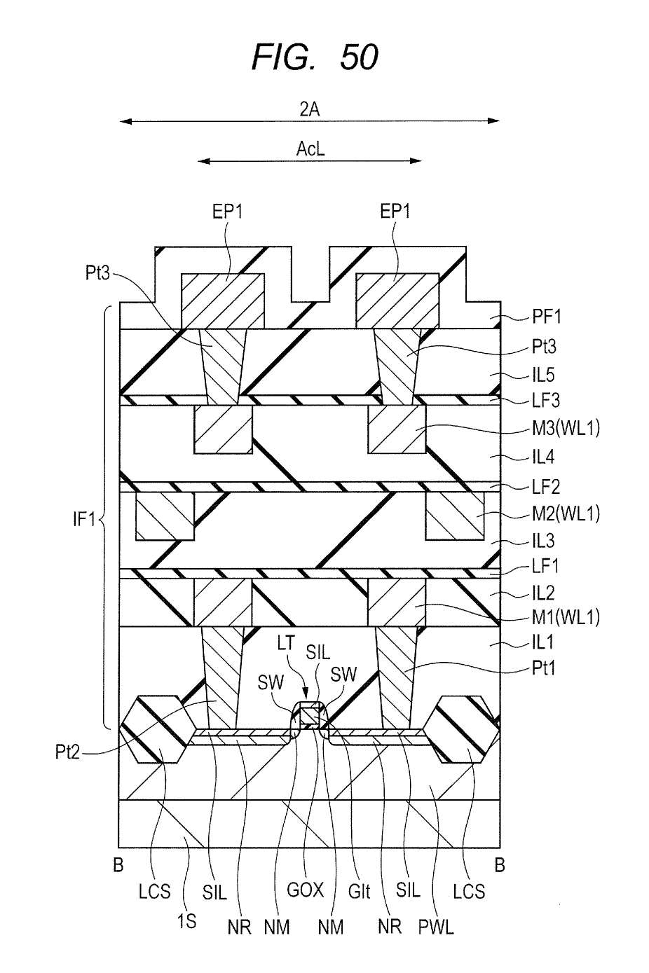

Subsequently, a plug Pt3, which reaches the wiring M3 by penetrating the interlayer insulating film IL5 and the liner film LF3, is formed in the peripheral circuit region 2A, as illustrated in FIG. 50. Also in the peripheral circuit region 2A, the electrode pad EP1 is formed over the interlayer insulating film IL5 so as to be electrically coupled to the plug Pt3.

Subsequently, as illustrated in FIGS. 49 and 50, a protective film PF1, including, for example, a silicon oxide films, is formed over the interlayer insulating film IL5 by a CVD method, etc., in the pixel region 1A and the peripheral circuit region 2A (Step S42 in FIG. 48). Also in the peripheral circuit region 2A, the protective film PF1 is formed over the interlayer insulating film IL5 so as to cover the electrode pad EP1.

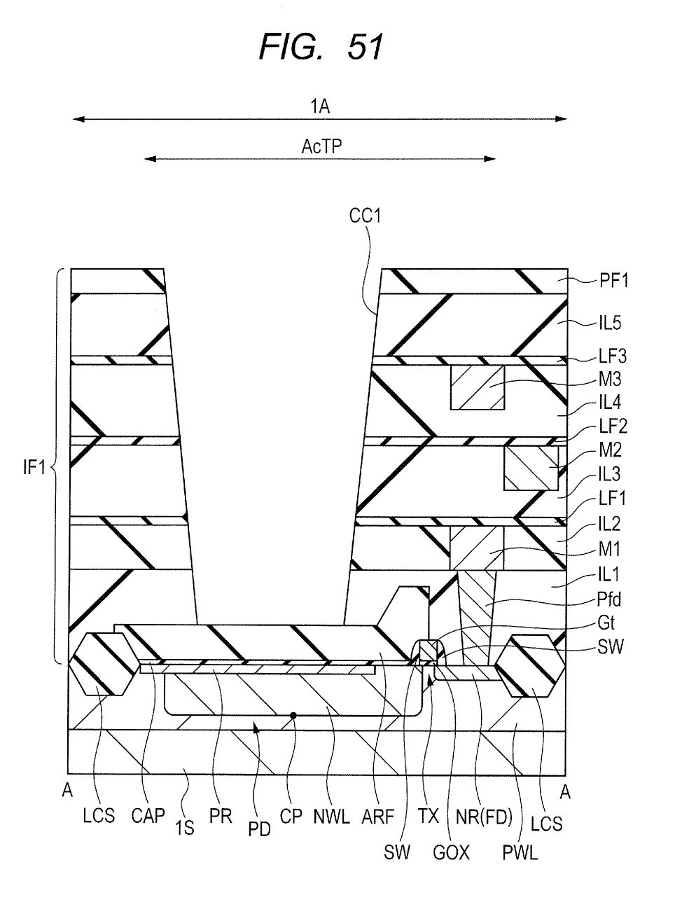

Subsequently, the concave portion CC1 is formed, as illustrated in FIG. 51 (Step S43 in FIG. 48). In Step S43, a concave portion CC1, which reaches the antireflection film ARF by penetrating the protective film PF1, the interlayer insulating films IL1 to IL5, and the liner films LF1 to LF3, is formed in the pixel region 1A. The concave portion CC1 is formed to overlap the center CP of the photodiode PD in plan view. When the interlayer insulating films IL1 to IL5, the liner films LF1 to LF3, the antireflection film ARF, and the cap insulating film CAP are collectively referred to as an insulating film part IF1, as described above, the concave portion CC1 is therefore formed in the upper surface of the insulating film part IF1 in a portion that overlaps the center CP of the photodiode PD in plan view. The specific step of forming the concave portion CC1 can be made the same as Step S22 in FIG. 12.

Subsequently, as illustrated in FIG. 46, the micro lens ML is formed on the top surface side of the supporting substrate 21S (Step S44 in FIG. 48). The supporting substrate 21S including, for example, a transparent glass substrate, etc., is first provided, and the micro lens ML is formed on a main surface side of the supporting substrate 21S, i.e., on the top surface side thereof, as illustrated in FIG. 46. Subsequently, as illustrated in FIG. 46, the color filter layer CF is formed over the top surface of the supporting substrate 21S so as to cover the micro lens ML (Step S45 in FIG. 48).

Subsequently, as illustrated in FIG. 46, the supporting substrate 21S, over the top surface of which the micro lens ML and the color filter layer CF are formed, is adhered to the protective film PF1, in the pixel region 1A (Step S46 in FIG. 48). The supporting substrate 21S is adhered to the semiconductor substrate 1S, in a state where the top surface of the supporting substrate 21S and that of the semiconductor substrate 1S face each other and the micro lens ML and the concave portion CC1 face each other, as illustrated in FIG. 46. Thereby, the color filter layer CF, formed over the top surface of the supporting substrate 21S so as to cover the micro lens ML, and the protective film PF1, formed over the top surface of the semiconductor substrate 1S, are adhered to each other. That is, the color filter layer CF, formed over the top surface of the supporting substrate 21S so as to cover the micro lens ML, and the insulating film part IF1, formed over the top surface of the semiconductor substrate 1S, are adhered to each other.

In this case, the color filter layer serving as a transmission film part is formed over the interlayer insulating film IL5 so as to close the concave portion CC1. That is, the color filter layer CF, serving as a transmission film part that transmits the incident light to enter the photodiode PD, is formed over the insulating film part IF1 so as to close the concave portion CC1. And, the space SP1 is formed by the concave portion CC1 and the color filter layer CF. As described above, the concave portion CC1 is formed in the upper surface of the insulating film part IF1 in a portion that overlaps the center CP of the photodiode PD in plan view. Accordingly, the space SP1 is arranged to overlap the center CP of the photodiode PD in plan view.

The transmission film part including the color filter layer CF is formed over the insulating film part IF1, and the micro lens ML is formed over the color filter layer CF in a portion located above the concave portion CC1.

The supporting substrate 21S, which has been adhered to the semiconductor substrate 1S, may be removed in a state where the color filter layer CF and the micro lens ML are left over the top surface of the semiconductor substrate 1S, similarly to First Embodiment.

On the other hand, in a portion of the supporting substrate 21S, the portion being located in the peripheral circuit region 2A in plan view when the supporting substrate 21S is adhered to the semiconductor substrate 1S, for example, an opening, etc., is formed. Accordingly, the supporting substrate 21S is not adhered to both the electrode pad EP1, exposed at the bottom of the opening OP2 of the protective film PF1, and the protective film PF1, in the peripheral circuit region 2A. Thus, the semiconductor device of Third Embodiment can be manufactured, as illustrated in FIGS. 46 and 47.

<Main Characteristics and Effects of Present Embodiment>

The semiconductor device of Third Embodiment has the same characteristics as those of the semiconductor device of First Embodiment, such as, for example, the fact that the space SP1 is arranged to overlap the center CP of the photodiode PD in plan view, and hence the semiconductor device of Third Embodiment has the same effects as those of the semiconductor device of First Embodiment.

In addition to that, the concave portion CC1 is closed by adhering the supporting substrate 21S in which the micro lens ML and the color filter layer CF are formed, in the semiconductor device of Third Embodiment. Thereby, when the concave portion CC1 is closed, a state where the concave portion CC1 is closed by the supporting substrate 21S can be maintained, and hence the concave portion CC1 can be further easily closed in comparison with First Embodiment having a state where the concave portion CC1 is closed only by the transmission film TF1 during the manufacture of the semiconductor device.

The invention made by the present inventors has been specifically described above based on preferred embodiments, but the invention should not be limited to the embodiments, and it is needless to say that various modifications may be made to the invention within a range not departing from the gist of the invention.

What is claimed is:

1. A semiconductor device comprising:
a semiconductor substrate;
a photoelectric conversion element that is formed in a first main surface of the semiconductor substrate and receives incident light to convert into a charge;
an insulating film part that is formed over the first main surface of the semiconductor substrate so as to cover the photoelectric conversion element;
a concave portion that is formed in an upper surface of the insulating film part in a portion that overlaps a center of the photoelectric conversion element in plan view; and
a transmission film part that is formed over the insulating film part so as to close the concave portion and transmits the incident light,
wherein a space is formed by the concave portion and the transmission film part, and
wherein the space is arranged to overlap the center of the photoelectric conversion element in plan view.

2. The semiconductor device according to claim 1,
wherein the concave portion is formed, in plan view, in a region where the photoelectric conversion element is formed.

3. The semiconductor device according to claim 1, including:
a color filter layer formed over the transmission film part in a portion located above the concave portion; and
a micro lens formed over the color filter layer.

4. The semiconductor device according to claim 1,
wherein the transmission film part includes a silicon oxide film.

5. The semiconductor device according to claim 1, including a sidewall insulating film formed in a side surface of the concave portion.

6. The semiconductor device according to claim 5,
wherein the sidewall insulating film includes a silicon oxide film or a silicon nitride film.

7. The semiconductor device according to claim 1,
wherein the insulating film part comprises:
an interlayer insulating film formed over the first main surface of the semiconductor substrate so as to cover the photoelectric conversion element; and
a laminated insulating film in which each of a plurality of first insulating layers and each of a plurality of second insulating layers are alternately laminated over the interlayer insulating film, and
wherein each of the second insulating layers includes a material different from that of each of the first insulating layers,
wherein the concave portion reaches the interlayer insulating film by penetrating the laminated insulating film, and
wherein a wiring layer is formed by wiring formed in some of the first insulating layers.

8. The semiconductor device according to claim 1,
wherein the transmission film part is a color filter layer, and
wherein the semiconductor device further has a micro lens formed over the color filter layer in a portion located above the concave portion.

9. A manufacturing method of a semiconductor device comprising the steps of:
(a) forming, over a first main surface of a semiconductor substrate, a photoelectric conversion element that receives incident light to convert into a charge;
(b) forming an insulating film part over the first main surface of the semiconductor substrate so as to cover the photoelectric conversion element;
(c) forming a concave portion over an upper surface of the insulating film part in a portion that overlaps a center of the photoelectric conversion element in plan view; and
(d) forming a transmission film part that transmits the incident light over the insulating film part so as to close the concave portion,
wherein in the step (d), a space is formed by the concave portion and the transmission film part, and
wherein the space is arranged to overlap a center of the photoelectric conversion element in plan view.

10. The manufacturing method of a semiconductor device according to claim 9,
wherein the step (d) comprises the steps of:
(d1) forming the transmission film part over a second main surface of a lamination substrate;
(d2) joining together the transmission film part and the insulating film part by laminating the lamination substrate to the semiconductor substrate in a state where the second main surface of the lamination substrate and the first main surface of the semiconductor substrate face each other; and
(d3) removing the lamination substrate laminated to the semiconductor substrate in a state where the transmission film part is left over the first main surface of the semiconductor substrate.

11. The manufacturing method of a semiconductor device according to claim 9,
wherein in the step (c), the concave portion is formed, in plan view, in a region where the photoelectric conversion element is formed.

12. The manufacturing method of a semiconductor device according to claim 9, comprising the steps of:
(e) forming a color filter layer over the transmission film part in a portion located above the concave portion; and
(f) forming a micro lens over the color filter layer.

13. The manufacturing method of a semiconductor device according to claim 9,
wherein in the step (d), the transmission film part including a silicon oxide film is formed.

14. The manufacturing method of a semiconductor device according to claim 9, comprising the step of:
(g) before the step (d), forming a sidewall insulating film over a side surface of the concave portion.

15. The manufacturing method of a semiconductor device according to claim 14,
wherein in the step (g), the sidewall insulating film including a silicon oxide film or a silicon nitride film is formed.

16. The manufacturing method of a semiconductor device according to claim 9,
wherein the step (b) comprises the steps of:
(b1) forming an interlayer insulating film over the first main surface of the semiconductor substrate so as to cover the photoelectric conversion element; and
(b2) forming a laminated insulating film, in which each of a plurality of first insulating layers and each of a plurality of second insulating layers are alternately laminated, over the interlayer insulating film,
wherein each of the second insulating layers includes a material different from that of each of the first insulating layers,
wherein in the step (c), the concave portion, which reaches the interlayer insulating film by penetrating the laminated insulating film, is formed, and
wherein in the step (b2), a wiring layer is formed by forming wiring in some of the first insulating layers.

17. The manufacturing method of a semiconductor device according to claim 9,
wherein the step (d) comprises the steps of:
(d4) forming a micro lens on a third main surface side of a supporting substrate;
(d5) forming a color filter layer, serving as the transmission film part, over the third main surface of the supporting substrate so as to cover the micro lens; and
(d6) adhering together the color filter layer formed to cover the micro lens and the insulating film part, by adhering the supporting substrate to the semiconductor substrate in a state where the third main surface of the supporting substrate and the first main surface of the semiconductor substrate face each other and the micro lens and the concave portion face each other, in plan view.
